(19) United States
(12) Patent Application Publication
(10) Pub. No.: US 2026/0301777 A1
(43) Pub. Date: Oct. 1, 2026

(54) MEMORY DEVICE

(71) Applicant: KIOXIA CORPORATION, Tokyo (JP)

(72) Inventors: Katsuyoshi KOMATSU, Yokkaichi Mie (JP); Kenta CHOKAWA, Yokohama Kanagawa (JP); Takeshi IWASAKI, Kuwana Mie (JP); Yuya SATO, Fujisawa Kanagawa (JP); Masakazu GOTO, Moriya Ibaraki (JP); Tadaomi DAIBOU, Yokkaichi Mie (JP)

(73) Assignee: KIOXIA CORPORATION, Tokyo (JP)

(21) Appl. No.: 19/340,957

(22) Filed: Sep. 26, 2025

(30) Foreign Application Priority Data
Mar. 28, 2025 (JP) 2025-056519

(51) Int. Cl. G11C 5/06; H10B 63/00; H10N 70/00

(52) U.S. Cl. CPC G11C 5/063; H10B 63/20; H10N 70/8822; H10N 70/8825; H10N 70/8828; H10N 70/8833

(57) ABSTRACT

A memory device of embodiments includes a memory cell including a first conductive layer, a second conductive layer, a third conductive layer provided between the first conductive layer and the second conductive layer, a switching layer provided between the first conductive layer and the third conductive layer, and a variable resistance layer provided between the third conductive layer and the second conductive layer. The switching layer contains an oxide of zinc (Zn) and a compound of a first element and a second element, the first element being at least one element selected from a group consisting of zinc (Zn), tin (Sn), gallium (Ga), indium (In), and bismuth (Bi) and the second element being at least one element selected from a group consisting of tellurium (Te), sulfur(S), selenium (Se), and antimony (Sb).

### CROSS-REFERENCE TO RELATED APPLICATION

This application is based upon and claims the benefit of priority from Japanese Patent Application No. 2025-056519, filed on Mar. 28, 2025, the entire contents of which are incorporated herein by reference.

### FIELD

Embodiments described herein relate generally to a memory device.

### BACKGROUND

An example of a large-capacity nonvolatile memory device is a cross-point type two-terminal memory device. In the cross-point type two-terminal memory device, scaling-down and high integration of memory cells are easy.

Each memory cell in the cross-point type two-terminal memory device has, for example, a variable resistance element and a switching element. Since the memory cell has a switching element, the current flowing through memory cells other than the selected memory cell is suppressed.

The switching element is required to have excellent characteristics, such as low leakage current, high on-current, and high reliability.

### BRIEF DESCRIPTION OF THE DRAWINGS

FIG. 1 is a block diagram of a memory device according to a first embodiment;

FIG. 2 is a schematic cross-sectional view of a memory cell in the memory device according to the first embodiment;

FIG. 3 is an explanatory diagram of a problem of the memory device according to the first embodiment;

FIG. 4 is an explanatory diagram of the current-voltage characteristics of a switching element in the first embodiment;

FIG. 5 is a schematic cross-sectional view of a memory cell in a memory device according to a first modification example of the first embodiment;

FIG. 6 is a schematic cross-sectional view of a memory cell in a memory device according to a second modification example of the first embodiment;

FIG. 7 is a schematic cross-sectional view of a memory cell in a memory device according to a third modification example of the first embodiment;

FIG. 8 is a schematic cross-sectional view of a memory cell in a memory device according to a second embodiment;

FIG. 9 is a schematic cross-sectional view of a memory cell in a memory device according to a third embodiment;

FIG. 10 is an explanatory diagram of the current-voltage characteristics of a memory element in the third embodiment;

FIG. 11 is an explanatory diagram of a first operation example of a memory operation of the memory device according to the third embodiment;

FIG. 12 is an explanatory diagram of a second operation example of the memory operation of the memory device according to the third embodiment;

FIG. 13 is an explanatory diagram of the current-voltage characteristics of a memory element in a first modification example of the third embodiment;

FIG. 14 is an explanatory diagram of a third operation example of a memory operation of a memory device according to the first modification example of the third embodiment;

FIG. 15 is an explanatory diagram of a fourth operation example of the memory operation of the memory device according to the first modification example of the third embodiment;

FIG. 16 is an explanatory diagram of the current-voltage characteristics of a memory element in a second modification example of the third embodiment;

FIG. 17 is an explanatory diagram of a fifth operation example of a memory operation of a memory device according to the second modification example of the third embodiment;

FIG. 18 is an explanatory diagram of a sixth operation example of the memory operation of the memory device according to the second modification example of the third embodiment;

FIG. 19 is an explanatory diagram of the current-voltage characteristics of a memory element in a third modification example of the third embodiment;

FIG. 20 is an explanatory diagram of a seventh operation example of a memory operation of a memory device according to the third modification example of the third embodiment; and

FIG. 21 is an explanatory diagram of an eighth operation example of the memory operation of the memory device according to the third modification example of the third embodiment.

### DETAILED DESCRIPTION

A memory device of embodiments includes a memory cell including a first conductive layer, a second conductive layer, a third conductive layer provided between the first conductive layer and the second conductive layer, a switching layer provided between the first conductive layer and the third conductive layer, and a variable resistance layer provided between the third conductive layer and the second conductive layer. The switching layer contains an oxide of zinc (Zn) and a compound of a first element and a second element, the first element being at least one element selected from a group consisting of zinc (Zn), tin (Sn), gallium (Ga), indium (In), and bismuth (Bi) and the second element being at least one element selected from a group consisting of tellurium (Te), sulfur(S), selenium (Se), and antimony (Sb).

Hereinafter, embodiments will be described with reference to the diagrams. In addition, in the following description, the same or similar members and the like are denoted by the same reference numerals, and the description of the members and the like once described will be omitted as appropriate.

The qualitative analysis and quantitative analysis of the chemical composition forming the memory device in this specification can be performed by, for example, Rutherford Backscattering Spectroscopy (RBS), secondary ion mass spectroscopy (SIMS), energy dispersive X-ray spectroscopy (EDX), or electron energy loss spectroscopy (EELS). In addition, when measuring the thickness of each member forming the memory device, a distance between members, and the like, for example, a transmission electron microscope (TEM) can be used. In addition, for the identification of the constituent materials of members forming the memory device and the measurement of an abundance ratio, a bonding state, a local structure (interatomic distance, coordination number), and a chemical state, for example, X-ray photoelectron spectroscopy (XPS), X-ray absorption fine structure (XAFS), Raman spectroscopy (Raman), or EELS can be used.

### First Embodiment

A memory device according to a first embodiment includes a memory cell including a first conductive layer, a second conductive layer, a third conductive layer provided between the first conductive layer and the second conductive layer, a switching layer provided between the first conductive layer and the third conductive layer, and a variable resistance layer provided between the third conductive layer and the second conductive layer. The switching layer contains an oxide of zinc (Zn) and a compound of a first element, which is at least one element selected from a group consisting of zinc (Zn), tin (Sn), gallium (Ga), indium (In), and bismuth (Bi), and a second element, which is at least one element selected from a group consisting of tellurium (Te), sulfur(S), selenium (Se), and antimony (Sb).

In addition, the memory device according to the first embodiment further includes a plurality of first wirings and a plurality of second wirings crossing the plurality of first wirings. In addition, the memory cell is provided in a region where one of the plurality of first wirings and one of the plurality of second wirings cross each other.

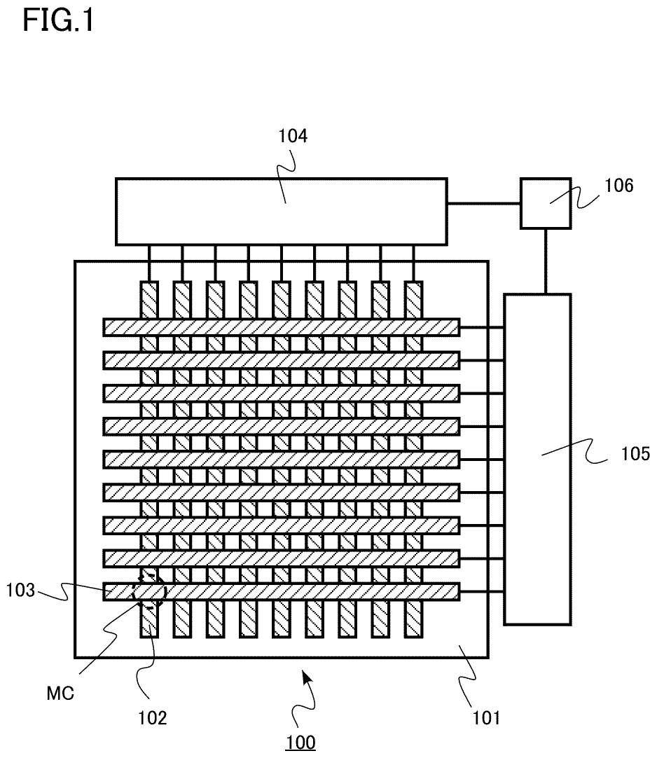

FIG. 1 is a block diagram of the memory device according to the first embodiment.

A memory cell array 100 in the memory device according to the first embodiment includes, for example, a plurality of word lines 102 and a plurality of bit lines 103 crossing the word lines 102 on a semiconductor substrate 101 with an insulating layer interposed therebetween. The bit lines 103 are provided in a layer above the word lines 102, for example. In addition, a first control circuit 104, a second control circuit 105, and a sense circuit 106 are provided as peripheral circuits around the memory cell array 100.

The word line 102 is an example of the first wiring. In addition, the bit line 103 is an example of the second wiring.

A plurality of memory cells MC are provided in regions where the word lines 102 and the bit lines 103 cross each other. The memory device according to the first embodiment is a two-terminal magnetoresistive memory having a cross-point structure.

Each of the plurality of word lines 102 is connected to the first control circuit 104. In addition, each of the plurality of bit lines 103 is connected to the second control circuit 105. The sense circuit 106 is connected to the first control circuit 104 and the second control circuit 105.

The first control circuit 104 and the second control circuit 105 have functions of selecting a desired memory cell MC, writing data to the memory cell MC, reading data from the memory cell MC, and deleting data from the memory cell MC, for example. When reading data, the data in the memory cell MC is read as the amount of current flowing between the word line 102 and the bit line 103 or as an electric potential change of the bit line 103. The sense circuit 106 has a function of determining the amount of current to determine the polarity of the data. For example, “0” and “1” of data are determined.

The first control circuit 104, the second control circuit 105, and the sense circuit 106 are electronic circuits using semiconductor devices formed on the semiconductor substrate 101, for example.

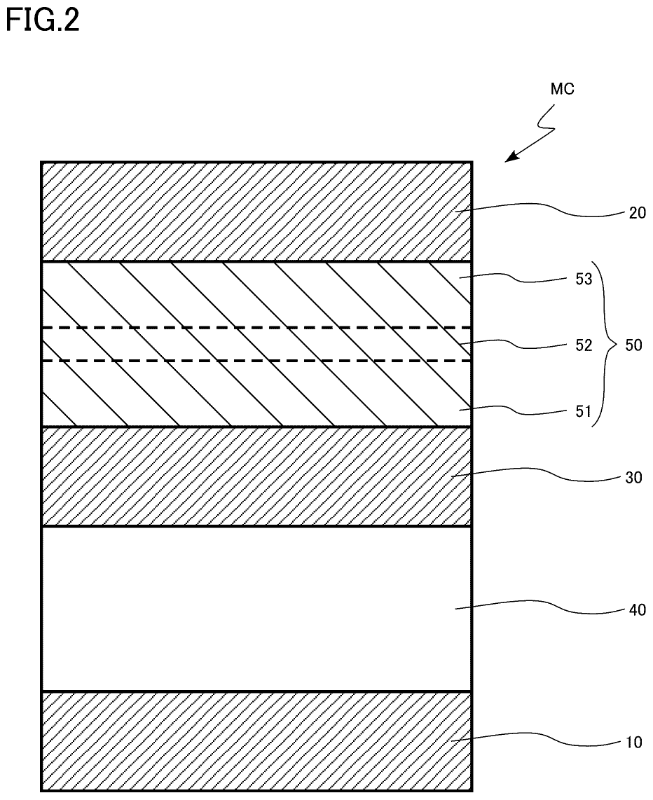

FIG. 2 is a schematic cross-sectional view of a memory cell in the memory device according to the first embodiment. FIG. 2 shows a cross section of one memory cell MC indicated by, for example, a dotted circle in the memory cell array 100 of FIG. 1.

As shown in FIG. 2, the memory cell MC includes a lower electrode 10, a upper electrode 20, an intermediate electrode 30, a switching layer 40, and a variable resistance layer 50. The variable resistance layer 50 includes a fixed layer 51, a tunnel layer 52, and a free layer 53.

The lower electrode 10 is an example of the first conductive layer. The upper electrode 20 is an example of the second conductive layer. The intermediate electrode 30 is an example of the third conductive layer.

The lower electrode 10, the switching layer 40, and the intermediate electrode 30 form a switching element of the memory cell MC. The intermediate electrode 30, the variable resistance layer 50, and the upper electrode 20 form a variable resistance element of the memory cell MC.

The lower electrode 10 is connected to the word line 102. The lower electrode 10 is, for example, a metal. The lower electrode 10 contains, for example, at least one material selected from a group consisting of titanium, titanium nitride, carbon, carbon nitride, tungsten, tungsten carbide, and tungsten nitride. The lower electrode 10 may be a part of the word line 102.

The upper electrode 20 is connected to the bit line 103. The upper electrode 20 is, for example, a metal. The upper electrode 20 contains, for example, at least one material selected from a group consisting of titanium, titanium nitride, carbon, carbon nitride, tungsten, tungsten carbide, and tungsten nitride. The upper electrode 20 may be a part of the bit line 103.

The intermediate electrode 30 is provided between the lower electrode 10 and the upper electrode 20. The intermediate electrode 30 is, for example, a metal. The intermediate electrode 30 contains, for example, at least one material selected from a group consisting of titanium, titanium nitride, carbon, carbon nitride, tungsten, tungsten carbide, and tungsten nitride.

The switching layer 40 is provided between the lower electrode 10 and the intermediate electrode 30. The thickness of the switching layer 40 in a first direction from the lower electrode 10 to the upper electrode 20 is, for example, equal to or more than 5 nm and equal to or less than 50 nm. It is preferable that the thickness of the switching layer 40 in the first direction from the lower electrode 10 to the upper electrode 20 is, for example, equal to or more than 5 nm and equal to or less than 20 nm.

The switching layer 40 has a function of suppressing an increase in half-select leakage current flowing through a half-selected cell. The switching layer 40 has a nonlinear current-voltage characteristic that a current increases abruptly at a specific threshold voltage.

The switching layer 40 contains an oxide of zinc (Zn). The switching layer 40 contains, for example, a zinc oxide.

The switching layer 40 contains a compound of a first element, which is at least one element selected from a group consisting of zinc (Zn), tin (Sn), gallium (Ga), indium (In), and bismuth (Bi), and a second element, which is at least one element selected from a group consisting of tellurium (Te), sulfur(S), selenium (Se), and antimony (Sb).

The switching layer 40 contains, for example, a chalcogenide. The chalcogenide is a compound in which tellurium (Te), sulfur(S), or selenium (Se), which is a chalcogen element, is combined with other elements.

The switching layer 40 contains, for example, at least one chalcogenide selected from a group consisting of zinc telluride, tin telluride, gallium telluride, indium telluride, bismuth telluride, zinc sulfide, tin sulfide, gallium sulfide, indium sulfide, bismuth sulfide, zinc selenide, tin selenide, gallium selenide, indium selenide, and bismuth selenide. Since telluride has a smaller bandgap than sulfide and selenide, the write voltage can be relatively reduced. Therefore, telluride has an advantage of being able to suppress fluctuations in characteristics, such as fluctuations in half-select leakage current and fluctuations in on-current, when repeating writing.

The switching layer 40 contains, for example, at least one compound selected from a group consisting of tin antimonide, gallium antimonide, indium antimonide, and bismuth antimonide.

The switching layer 40 contains, for example, an oxide of at least one third element selected from a group consisting of zirconium (Zr), silicon (Si), hafnium (Hf), and aluminum (Al). The switching layer 40 contains, for example, at least one oxide selected from a group consisting of zirconium oxide, silicon oxide, hafnium oxide, and aluminum oxide.

Whether or not the switching layer 40 contains an oxide of zinc (Zn) or an oxide of the third element can be determined by using, for example, X-ray photoelectron spectroscopy (XPS) or electron energy loss spectroscopy (EELS). For example, whether or not the switching layer 40 contains an oxide of zinc (Zn) can be determined by checking whether or not the switching layer 40 contains a bond between zinc (Zn) and oxygen (O), that is, a Zn—O bond, using X-ray photoelectron spectroscopy (XPS) or electron energy loss spectroscopy (EELS).

Whether or not the switching layer 40 contains a compound of the first element and the second element can be determined by using, for example, X-ray absorption fine structure (XAFS), Raman spectroscopy (Raman), or electron energy loss spectroscopy (EELS). For example, whether or not the switching layer 40 contains a compound of the first element and the second element can be determined by checking whether or not the switching layer 40 contains a bond between the first element and the second element using X-ray absorption fine structure (XAFS), Raman spectroscopy (Raman), or electron energy loss spectroscopy (EELS). For example, when the first element is tin (Sn) and the second element is tellurium (Te), it is possible to determine whether or not the switching layer 40 contains a compound of tin (Sn) and tellurium (Te) by checking whether or not the switching layer 40 contains an Sn—Te bond.

The switching layer 40 contains, for example, a mixture of the above compound and an oxide of zinc (Zn). The oxide of zinc (Zn) and the above compound are present in the switching layer 40, for example, in a mixed state.

The sum of the atomic concentrations of zinc (Zn), the first element, the second element, and oxygen (O) In the switching layer 40 is, for example, equal to or more than 80%. For example, when the first element is tin (Sn) and the second element is tellurium (Te), the sum of the atomic concentrations of zinc (Zn), tin (Sn), tellurium (Te), and oxygen (O) in the switching layer 40 is, for example, equal to or more than 80%.

The ratio of the sum of the atomic concentrations of zinc (Zn) and oxygen (O) to the sum of the atomic concentrations of zinc (Zn), the first element, the second element, and oxygen (O) in the switching layer 40 is, for example, equal to or more than 20% and equal to or less than 90%. For example, when the first element is tin (Sn) and the second element is tellurium (Te), the ratio ((Zn+O)/(Zn+Sn+Te+O)) of the sum of the atomic concentrations of zinc (Zn) and oxygen (O) to the sum of the atomic concentrations of zinc (Zn), tin (Sn), tellurium (Te), and oxygen (O) in the switching layer 40 is, for example, equal to or more than 20% and equal to or less than 90%.

The ratio of the sum of the atomic concentrations of the first element and the second element to the sum of the atomic concentrations of zinc (Zn), the first element, the second element, and oxygen (O) in the switching layer 40 is, for example, equal to or more than 5% and equal to or less than 65%. For example, when the first element is tin (Sn) and the second element is tellurium (Te), the ratio ((Sn+Te)/(Zn+Sn+Te+O)) of the sum of the atomic concentrations of tin (Sn) and tellurium (Te) to the sum of the atomic concentrations of zinc (Zn), tin (Sn), tellurium (Te), and oxygen (O) in the switching layer 40 is, for example, equal to or more than 5% and equal to or less than 65%.

When the switching layer 40 contains an oxide of the third element, the atomic concentration of zinc (Zn) in the switching layer 40 is higher than the atomic concentration of the third element in the switching layer 40.

When the switching layer 40 contains an oxide of the third element, the molar concentration of the oxide of zinc (Zn) in the switching layer 40 is higher than, for example, the molar concentration of the oxide of the third element in the switching layer 40. The molar concentration of the oxide of the third element in the switching layer 40 is, for example, equal to or more than 10% and less than 50% of the molar concentration of the oxide of zinc (Zn) in the switching layer 40.

When the switching layer 40 contains an oxide of the third element and the first element is zinc (Zn), the ratio of the sum of the atomic concentrations of zinc (Zn) and oxygen (O) to the sum of the atomic concentrations of zinc (Zn), the first element, the second element, the third element, and oxygen (O) in the switching layer 40 is, for example, equal to or more than 40% and equal to or less than 85%. For example, when the second element is tellurium (Te) and the third element is zirconium (Zr), the ratio ((Zn+O)/(Zn+Te+Zr+O)) of the sum of the atomic concentrations of zinc (Zn) and oxygen (O) to the sum of the atomic concentrations of zinc (Zn), tellurium (Te), zirconium (Zr), and oxygen (O) in the switching layer 40 is, for example, equal to or more than 40% and equal to or less than 85%.

When the switching layer 40 contains an oxide of the third element and the first element is zinc (Zn), the ratio of the atomic concentration of zinc (Zn) to the sum of the atomic concentrations of zinc (Zn), the first element, the second element, the third element, and oxygen (O) in the switching layer 40 is, for example, equal to or more than 10% and equal to or less than 55%. For example, when the second element is tellurium (Te) and the third element is zirconium (Zr), the ratio ((Zn)/(Zn+Te+Zr+O)) of the atomic concentration of zinc (Zn) to the sum of the atomic concentrations of zinc (Zn), tellurium (Te), zirconium (Zr), and oxygen (O) in the switching layer 40 is, for example, equal to or more than 10% and equal to or less than 55%.

When the switching layer 40 contains an oxide of the third element and the first element is zinc (Zn), the ratio of the sum of the atomic concentrations of zinc (Zn) and the second element to the sum of the atomic concentrations of zinc (Zn), the first element, the second element, the third element, and oxygen (O) in the switching layer 40 is, for example, equal to or more than 30% and equal to or less than 65%. For example, when the second element is tellurium (Te) and the third element is zirconium (Zr), the ratio ((Zn+Te)/(Zn+Te+Zr+O)) of the sum of the atomic concentrations of zinc (Zn) and tellurium (Te) to the sum of the atomic concentrations of zinc (Zn), tellurium (Te), zirconium (Zr), and oxygen (O) in the switching layer 40 is, for example, equal to or more than 30% and equal to or less than 65%.

When the switching layer 40 contains an oxide of the third element and the first element is zinc (Zn), for example, the atomic concentration of zinc (Zn) in the switching layer 40 is higher than the atomic concentration of the second element in the switching layer 40, and the ratio of the difference between the atomic concentration of zinc (Zn) and the atomic concentration of the second element to the sum of the atomic concentrations of zinc (Zn), the first element, the second element, the third element, and oxygen (O) is greater than 20% and equal to or less than 40%. For example, when the second element is tellurium (Te) and the third element is zirconium (Zr), the ratio ((Zn−Te)/(Zn+Te+Zr+O)) of the difference between the atomic concentration of zinc (Zn) and the atomic concentration of tellurium (Te) to the sum of the atomic concentrations of zinc (Zn), tellurium (Te), zirconium (Zr), and oxygen (O) in the switching layer 40 is, for example, greater than 20% and equal to or less than 40%.

For example, at least a part of the switching layer 40 is crystalline. For example, at least a part of the oxide of zinc (Zn) is crystalline. In addition, for example, at least a part of the compound of the first element and the second element is crystalline. In addition, for example, at least a part of the oxide of the third element is crystalline. In addition, the switching layer 40 may be entirely amorphous.

When the first element is zinc (Zn) and the second element is tellurium (Te), it is preferable that at least a part of zinc telluride, which is a compound of zinc and tellurium contained in the switching layer 40, is crystalline. The zinc telluride may be entirely amorphous.

Whether or not the switching layer 40 is crystalline and whether or not the oxide or the compound is crystalline can be determined by using, for example, an electron beam diffraction method.

The switching layer 40 contains, for example, a fourth element that is at least one element selected from a group consisting of carbon (C), boron (B), nitrogen (N), germanium (Ge), silicon (Si), and aluminum (Al). The atomic concentration of the fourth element contained in the switching layer 40 is, for example, equal to or more than 5% and equal to or less than 20%.

The switching layer 40 can be formed by using, for example, a sputtering method. The switching layer 40 containing an oxide of zinc (Zn) and a compound of the second element and the third element can be formed by using, for example, a co-sputtering method using a first target formed of the oxide of zinc (Zn) and a second target formed of the compound of the second element and the third element. In addition, when the switching layer 40 further contains an oxide of the third element, the switching layer 40 can be formed by using, for example, a co-sputtering method using a first target formed of the oxide of zinc (Zn), a second target formed of the compound of the second element and the third element, and a third target formed of the oxide of the third element.

When forming the switching layer 40, the oxide of zinc (Zn) can be stably formed in the switching layer 40 by using the first target formed of the oxide of zinc (Zn), for example.

The variable resistance layer 50 is provided between the intermediate electrode 30 and the upper electrode 20. The variable resistance layer 50 includes a fixed layer 51, a tunnel layer 52, and a free layer 53. The variable resistance layer 50 includes a magnetic tunnel junction formed by the fixed layer 51, the tunnel layer 52, and the free layer 53.

The variable resistance layer 50 has a function of storing data by resistance change. The variable resistance layer 50 has, for example, a characteristic that the electrical resistance changes with the application of a predetermined voltage.

The fixed layer 51 is a ferromagnetic material. In the fixed layer 51, its magnetization direction does not change with respect to a predetermined write voltage, but is fixed to a specific direction.

The tunnel layer 52 is an insulator. Electrons pass through the tunnel layer 52 by the tunnel effect.

The free layer 53 is a ferromagnetic material. In the free layer 53, its magnetization direction changes with respect to a predetermined write voltage. The magnetization direction of the free layer 53 can be parallel to the magnetization direction of the fixed layer 51 or can be antiparallel to the magnetization direction of the fixed layer 51. For example, by applying a voltage between the intermediate electrode 30 and the upper electrode 20 so that a current flows between the intermediate electrode 30 and the upper electrode 20, the magnetization direction of the free layer 53 can be changed.

By changing the magnetization direction of the free layer 53, the electrical resistance of the variable resistance layer 50 changes. When the magnetization direction of the free layer 53 is antiparallel to the magnetization direction of the fixed layer 51, a high resistance state in which a current hardly flows is realized. On the other hand, when the magnetization direction of the free layer 53 is parallel to the magnetization direction of the fixed layer 51, a low resistance state in which a current flows easily is realized. In addition, the arrangement of the fixed layer 51 and the free layer 53 may be reversed. That is, the intermediate electrode 30, the free layer 53, the tunnel layer 52, the fixed layer 51, and the upper electrode 20 may be stacked in this order.

Next, the function and effect of the memory device according to the first embodiment will be described.

In the memory device according to the first embodiment, the resistance of the variable resistance layer 50 is changed by changing the magnetization direction of the free layer 53 as described above. When the magnetization direction of the free layer 53 is antiparallel to the magnetization direction of the fixed layer 51, a high resistance state in which a current hardly flows is realized. On the other hand, when the magnetization direction of the free layer 53 is parallel to the magnetization direction of the fixed layer 51, a low resistance state in which a current flows easily is realized.

For example, the high resistance state of the variable resistance layer 50 is defined as data “1”, and the low resistance state of the variable resistance layer 50 is defined as data “0”. Since the memory cell MC can maintain different resistance states, it is possible to store 1-bit data of “0” and “1”. Writing to one memory cell MC is performed by applying a voltage between the bit line 103 and the word line 102 connected to the memory cell MC so that a current flows between the bit line 103 and the word line 102 connected to the memory cell MC.

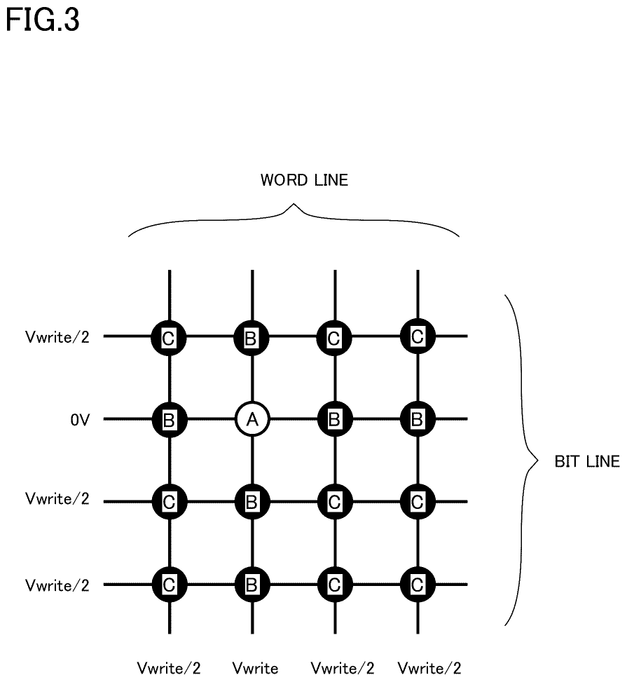

FIG. 3 is an explanatory diagram of a problem of the memory device according to the first embodiment. FIG. 3 shows a voltage applied to the memory cell MC when one memory cell MC in the memory cell array is selected for a write operation. The intersection of word lines and bit lines represents each memory cell MC.

The selected memory cell MC is a memory cell A (selected cell). A write voltage Vwrite is applied to the word line connected to the memory cell A. In addition, 0 V is applied to the bit line connected to the memory cell A.

Hereinafter, a case in which half (Vwrite/2) the write voltage is applied to the word lines and bit lines that are not connected to the memory cell A will be described as an example.

A voltage applied to memory cells C (non-selected cells) connected to the word lines and bit lines that are not connected to the memory cell A is 0 V. That is, no voltage is applied.

On the other hand, half (Vwrite/2) the write voltage Vwrite is applied to memory cells B (half-selected cells) connected to the word lines or bit lines connected to the memory cell A. Therefore, a half-select leakage current flows through the memory cell B (half-selected cell).

In addition, as an application method other than those described above, a method may be used in which half the write voltage (Vwrite/2) is applied to the word line connected to the memory cell A, a negative voltage (Vwrite/2) of half the write voltage is applied to the bit line, and 0 V is applied to the word line and the bit line that are not connected to the memory cell A.

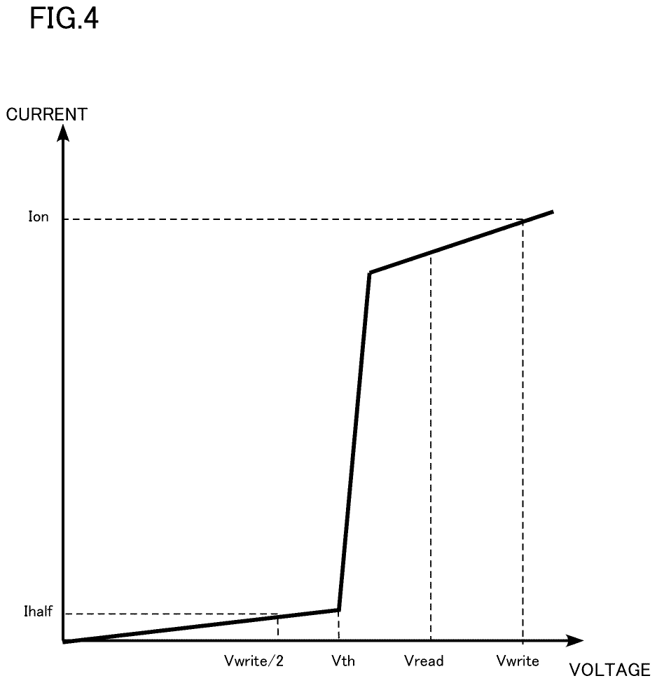

FIG. 4 is an explanatory diagram of the current-voltage characteristics of a switching element in the first embodiment. The horizontal axis indicates a voltage applied to the switching element, and the vertical axis indicates a current flowing through the switching element.

The switching element has a nonlinear current-voltage characteristic that a current increases abruptly at a threshold voltage Vth. The threshold voltage Vth is, for example, equal to or more than 0.5 V and equal to or less than 3 V.

The write voltage Vwrite is set such that the write voltage Vwrite is higher than the threshold voltage Vth and half (Vwrite/2) the write voltage Vwrite is lower than the threshold voltage Vth. The current flowing through the switching element when the write voltage Vwrite is applied is an on-current (Ion in FIG. 4). The current flowing through the switching element when half (Vwrite/2) the write voltage Vwrite is applied is a half-select leakage current (Ihalf in FIG. 4).

In addition, a read voltage Vread of the memory cell MC is set to a voltage higher than the threshold voltage Vth and lower than the write voltage Vwrite, as shown in FIG. 4, for example. Therefore, the half-select leakage current flowing through the half-selected cell can also be suppressed when reading the memory cell MC.

If the half-select leakage current is large, for example, the power consumption of the chip increases. In addition, for example, a voltage drop in the wiring increases and accordingly, a sufficiently high voltage is not applied to the selected cell. As a result, an operation for writing to the memory cell MC becomes unstable. In addition, if the on-current is small, for example, the current flowing through the selected cell is insufficient, resulting in insufficient writing to the memory cell MC. Therefore, as the current-voltage characteristics of the switching element, it is required to have both a low half-select leakage current and a high on-current.

In addition, high reliability is required for the current-voltage characteristics of the switching element. That is, it is required to realize high reliability by suppressing fluctuations in characteristics, such as fluctuations in half-select leakage current and fluctuations in on-current, when repeating data writing to the memory cell MC.

The switching layer 40 of the switching element in the first embodiment contains an oxide of zinc (Zn) and a compound of the first element and the second element. Since the switching layer 40 contains the oxide of zinc (Zn) and the compound of the first element and the second element, a low half-select leakage current and suppression of fluctuations in characteristics can be realized.

The inventors' study using simulations has revealed that when the switching layer 40 contains an oxide of zinc (Zn), the number of metallic bonds contained in the switching layer 40 is reduced. For example, the number of metallic bonds contained in the switching layer 40 is reduced compared to when the switching layer 40 contains an oxide of zirconium (Zr).

The metallic bond contained in the switching layer 40 is, for example, a bond between zinc (Zn) and zinc (Zn), a bond between the first element and the first element, or a bond between the second element and the second element.

The metallic bonds contained in the switching layer 40 are a factor in increasing the leakage current. Therefore, in the switching element in the first embodiment, a low half-select leakage current of the switching element is realized by reducing the number of metallic bonds contained in the switching layer 40.

In addition, the inventors' study using simulations has revealed that when the switching layer 40 contains an oxide of zinc (Zn), the number of bonds between the first element and oxygen (O) and between the first element and the second element contained in the switching layer 40 is increased. For example, compared to when the switching layer 40 contains an oxide of zirconium (Zr), the number of bonds between the first element and oxygen (O) and between the first element and the second element contained in the switching layer 40 is increased.

By increasing the number of bonds between the first element and oxygen (O) and between the first element and the second element contained in the switching layer 40, fluctuations in the characteristics of the switching element can be suppressed. This is believed to be because an increase in the number of bonds between the first element contained in the switching layer 40 and oxygen (O) suppresses the movement of the first element in the switching layer 40. In addition, this is believed to be because an increase in the number of bonds between the first element and the second element contained in the switching layer 40 makes it possible for a high on-current to flow through the switching element and accordingly, for example, dielectric breakdown of the switching element is suppressed.

Therefore, according to the first embodiment, it is possible to realize a low half-select leakage current of the switching element and suppress fluctuations in the characteristics of the switching element.

In particular, when the first element is zinc (Zn), there is a significant decrease in the number of metallic bonds contained in the switching layer 40 or a significant increase in the number of bonds between zinc (Zn), which is the first element contained in the switching layer 40, and oxygen (O) and between zinc (Zn), which is the first element, and the second element. Therefore, from the viewpoint of realizing a low half-select leakage current of the switching element and suppressing fluctuations in the characteristics of the switching element, it is preferable that the first element contained in the switching layer 40 is zinc (Zn).

From the viewpoint of improving the characteristics of the switching element, it is preferable that the first element contained in the switching layer 40 is zinc (Zn) and the second element is tellurium (Te).

From the viewpoint of improving the characteristics of the switching element, it is preferable that the sum of the atomic concentrations of zinc (Zn), the first element, the second element, and oxygen (O) in the switching layer 40 is equal to or more than 80%.

From the viewpoint of improving the characteristics of the switching element, it is preferable that the ratio of the sum of the atomic concentrations of zinc (Zn) and oxygen (O) to the sum of the atomic concentrations of zinc (Zn), the first element, the second element, and oxygen (O) in the switching layer 40 is equal to or more than 20% and equal to or less than 90%.

From the viewpoint of improving the characteristics of the switching element, it is preferable that the ratio of the sum of the atomic concentrations of the first element and the second element to the sum of the atomic concentrations of zinc (Zn), the first element, the second element, and oxygen (O) in the switching layer 40 is equal to or more than 5% and equal to or less than 65%.

From the viewpoint of realizing a low half-select leakage current of the switching element, it is preferable that the switching layer 40 contains an oxide of at least one third element selected from a group consisting of, for example, zirconium (Zr), silicon (Si), hafnium (Hf), and aluminum (Al). It is believed that, by the switching layer 40 containing an oxide of the third element, the number of oxygen vacancies in the switching layer 40, which are a cause of an increase in leakage current, is reduced, thereby reducing the half-select leakage current of the switching element.

When the switching layer 40 contains an oxide of the third element, it is preferable that the atomic concentration of zinc (Zn) in the switching layer 40 is higher than the atomic concentration of the third element in the switching layer 40 from the viewpoint of improving the characteristics of the switching element.

From the viewpoint of improving the characteristics of the switching element, it is preferable that the switching layer 40 contains an oxide of the third element, the first element is zinc (Zn), and the ratio of the sum of the atomic concentrations of zinc (Zn) and oxygen (O) to the sum of the atomic concentrations of zinc (Zn), the first element, the second element, the third element, and oxygen (O) in the switching layer 40 is equal to or more than 40% and equal to or less than 85%.

From the viewpoint of improving the characteristics of the switching element, it is preferable that the switching layer 40 contains an oxide of the third element, the first element is zinc (Zn), and the ratio of the atomic concentration of zinc (Zn) to the sum of the atomic concentrations of zinc (Zn), the first element, the second element, the third element, and oxygen (O) in the switching layer 40 is equal to or more than 10% and equal to or less than 55%.

From the viewpoint of improving the characteristics of the switching element, it is preferable that the switching layer 40 contains an oxide of the third element, the first element is zinc (Zn), and the ratio of the atomic concentrations of zinc (Zn) and the second element to the sum of the atomic concentrations of zinc (Zn), the first element, the second element, the third element, and oxygen (O) in the switching layer 40 is equal to or more than 30% and equal to or less than 65%.

From the viewpoint of improving the characteristics of the switching element, it is preferable that the switching layer 40 contains an oxide of the third element, the first element is zinc (Zn), the atomic concentration of zinc (Zn) in the switching layer 40 is higher than the atomic concentration of the second element in the switching layer 40, and the ratio of the difference between the atomic concentration of zinc (Zn) and the atomic concentration of the second element to the sum of the atomic concentrations of zinc (Zn), the first element, the second element, the third element, and oxygen (O) is greater than 20%.

From the viewpoint of improving the characteristics of the switching element, it is preferable that the switching layer 40 contains a fourth element, which is at least one element selected from a group consisting of carbon (C), boron (B), nitrogen (N), germanium (Ge), silicon (Si), and aluminum (Al). From the viewpoint of further improving the characteristics of the switching element, it is preferable that the atomic concentration of the fourth element contained in the switching layer 40 is equal to or more than 5% and equal to or less than 20%.

From the viewpoint of improving the characteristics of the switching element, it is preferable that at least a part of the switching layer 40 is crystalline. From the viewpoint of improving the characteristics of the switching element, it is preferable that at least a part of the oxide of zinc (Zn) contained in the switching layer 40 is crystalline. In addition, from the viewpoint of improving the characteristics of the switching element, it is preferable that at least a part of the compound of the first element and the second element contained in the switching layer 40 is crystalline. In addition, from the viewpoint of improving the characteristics of the switching element, it is preferable that at least a part of the oxide of the third element contained in the switching layer 40 is crystalline. In addition, the switching layer 40 may be entirely amorphous.

When the first element is zinc (Zn) and the second element is tellurium (Te), it is preferable that at least a part of zinc telluride, which is a compound of zinc and tellurium contained in the switching layer 40, is crystalline from the viewpoint of improving the characteristics of the switching element. The zinc telluride may be entirely amorphous.

According to the first embodiment, it is possible to realize a memory device having a switching element with excellent characteristics such as low half-select leakage current and high reliability.

### First Modification Example

A memory device according to a first modification example of the first embodiment is different from the memory device according to the first embodiment in that the first conductive layer includes a first portion and a second portion and the first portion contains at least one element selected from hafnium (Hf), aluminum (Al), magnesium (Mg), zirconium (Zr), and titanium (Ti).

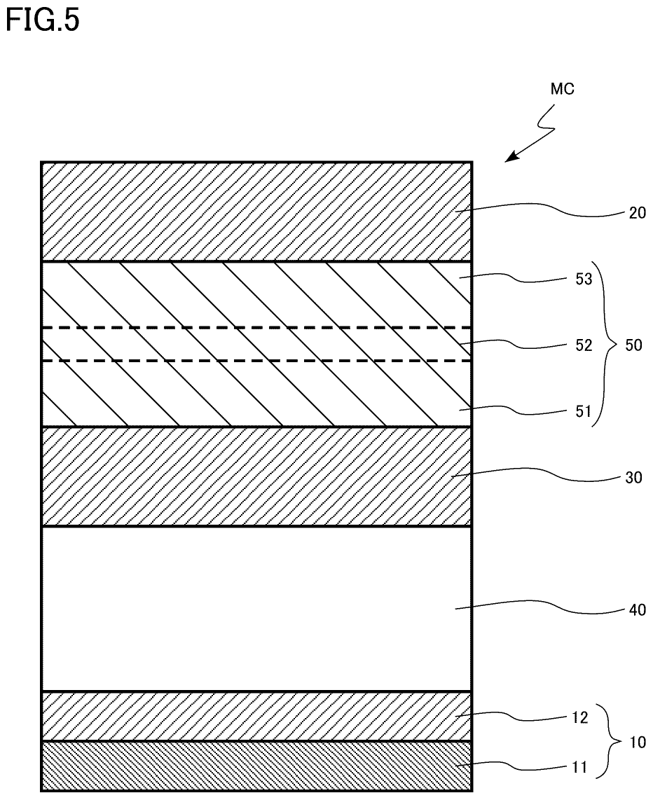

FIG. 5 is a schematic cross-sectional view of a memory cell in the memory device according to the first modification example of the first embodiment. FIG. 5 is a diagram corresponding to FIG. 2 in the first embodiment.

The lower electrode 10 includes a first portion 11 and a second portion 12. The second portion 12 is provided between the first portion 11 and the switching layer 40.

The first portion 11 contains at least one element selected from hafnium (Hf), aluminum (Al), magnesium (Mg), zirconium (Zr), and titanium (Ti). The first portion 11 contains, for example, borides of the above elements. The first portion 11 contains, for example, at least one material selected from a group consisting of hafnium, hafnium boride, aluminum magnesium boride, zirconium, zirconium boride, and titanium boride.

The second portion 12 contains, for example, at least one material selected from a group consisting of titanium, titanium nitride, carbon, carbon nitride, tungsten, tungsten carbide, and tungsten nitride.

In the memory device according to the first modification example of the first embodiment, since the first portion 11 of the lower electrode 10 contains at least one element selected from hafnium (Hf), aluminum (Al), magnesium (Mg), zirconium (Zr), and titanium (Ti), degradation of the characteristics of the variable resistance element is suppressed. In addition, since the first portion 11 is not in contact with the switching layer 40, desorption of oxygen (O) from the switching layer 40 is suppressed and accordingly, degradation of the characteristics of the switching element is suppressed.

As described above, according to the first modification example of the first embodiment, as in the first embodiment, it is possible to realize a switching element with excellent characteristics such as low half-select leakage current and high reliability.

### Second Modification Example

A memory device according to a second modification example of the first embodiment is different from the memory device according to the first embodiment in that the first conductive layer includes a first portion and a second portion, the first portion contains at least one element selected from hafnium (Hf), aluminum (Al), magnesium (Mg), zirconium (Zr), and titanium (Ti), the second conductive layer contains one element selected from hafnium (Hf), aluminum (Al), magnesium (Mg), zirconium (Zr), and titanium (Ti), the third conductive layer includes a third portion and a fourth portion, and the fourth portion contains at least one element selected from hafnium (Hf), aluminum (Al), magnesium (Mg), zirconium (Zr), and titanium (Ti).

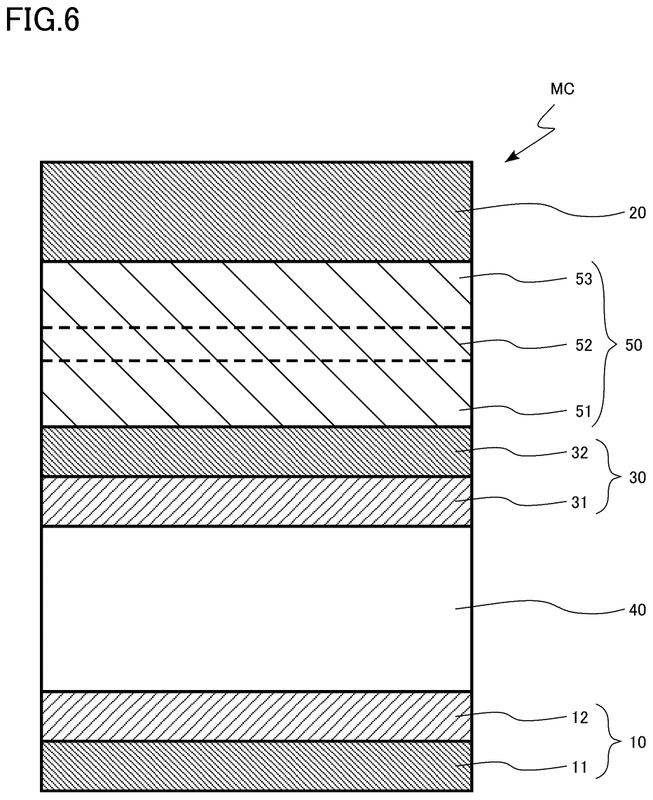

FIG. 6 is a schematic cross-sectional view of a memory cell in the memory device according to the second modification example of the first embodiment. FIG. 6 is a diagram corresponding to FIG. 2 in the first embodiment.

The lower electrode 10 includes a first portion 11 and a second portion 12. The second portion 12 is provided between the first portion 11 and the switching layer 40.

The first portion 11 contains at least one element selected from hafnium (Hf), aluminum (Al), magnesium (Mg), zirconium (Zr), and titanium (Ti). The first portion 11 contains, for example, borides of the above elements. The first portion 11 contains, for example, at least one material selected from a group consisting of hafnium, hafnium boride, magnesium aluminum boride, zirconium, zirconium boride, and titanium boride.

The second portion 12 contains, for example, at least one material selected from a group consisting of titanium, titanium nitride, carbon, carbon nitride, tungsten, tungsten carbide, and tungsten nitride.

The upper electrode 20 contains at least one element selected from hafnium (Hf), aluminum (Al), magnesium (Mg), zirconium (Zr), and titanium (Ti). The upper electrode 20 contains, for example, borides of the above elements. The upper electrode 20 contains, for example, at least one material selected from a group consisting of hafnium, hafnium boride, magnesium aluminum boride, zirconium, zirconium boride, and titanium boride.

The intermediate electrode 30 includes a third portion 31 and a fourth portion 32. The third portion 31 is provided between the fourth portion 32 and the switching layer 40.

The third portion 31 contains, for example, at least one material selected from a group consisting of titanium, titanium nitride, carbon, carbon nitride, tungsten, tungsten carbide, and tungsten nitride.

The fourth portion 32 contains at least one element selected from hafnium (Hf), aluminum (Al), magnesium (Mg), zirconium (Zr), and titanium (Ti). The fourth portion 32 contains, for example, borides of the above elements. The fourth portion 32 contains, for example, at least one material selected from a group consisting of hafnium, hafnium boride, magnesium aluminum boride, zirconium, zirconium boride, and titanium boride.

In the memory device according to the second modification example of the first embodiment, since the first portion 11 of the lower electrode 10, the upper electrode 20, and the fourth portion 32 of the intermediate electrode 30 contain at least one element selected from hafnium (Hf), aluminum (Al), magnesium (Mg), zirconium (Zr), and titanium (Ti), degradation of the characteristics of the variable resistance element is suppressed. In addition, since the first portion 11 of the lower electrode 10, the upper electrode 20, and the fourth portion 32 of the intermediate electrode 30 are not in contact with the switching layer 40, desorption of oxygen (O) from the switching layer 40 is suppressed and accordingly, degradation of the characteristics of the switching element is suppressed.

As described above, according to the second modification example of the first embodiment, as in the first embodiment, it is possible to realize a switching element with excellent characteristics such as low half-select leakage current and high reliability.

### Third Modification Example

A memory device according to a third modification example of the first embodiment is different from the memory device according to the first embodiment in that the first conductive layer includes a first portion, a second portion, and a fifth portion, the first portion contains at least one element selected from hafnium (Hf), aluminum (Al), magnesium (Mg), zirconium (Zr), and titanium (Ti), the second conductive layer contains at least one element selected from hafnium (Hf), aluminum (Al), magnesium (Mg), zirconium (Zr), and titanium (Ti), the third conductive layer includes a third portion and a fourth portion, and the fourth portion contains at least one element selected from hafnium (Hf), aluminum (Al), magnesium (Mg), zirconium (Zr), and titanium (Ti).

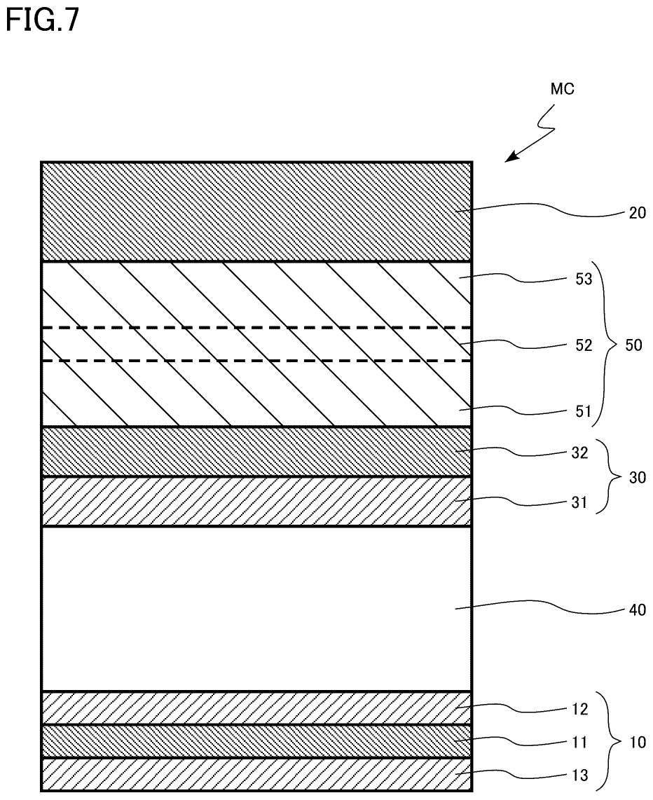

FIG. 7 is a schematic cross-sectional view of a memory cell in the memory device according to the third modification example of the first embodiment. FIG. 7 is a diagram corresponding to FIG. 2 in the first embodiment.

The lower electrode 10 includes a first portion 11, a second portion 12, and a fifth portion 13. The second portion 12 is provided between the first portion 11 and the switching layer 40. The first portion 11 is provided between the fifth portion 13 and the second portion 12.

The first portion 11 contains at least one element selected from hafnium (Hf), aluminum (Al), magnesium (Mg), zirconium (Zr), and titanium (Ti). The first portion 11 contains, for example, borides of the above elements. The first portion 11 contains, for example, at least one material selected from a group consisting of hafnium, hafnium boride, magnesium aluminum boride, zirconium, zirconium boride, and titanium boride.

The second portion 12 and the fifth portion 13 contain, for example, at least one material selected from a group consisting of titanium, titanium nitride, carbon, carbon nitride, tungsten, tungsten carbide, and tungsten nitride.

The upper electrode 20 contains at least one element selected from hafnium (Hf), aluminum (Al), magnesium (Mg), zirconium (Zr), and titanium (Ti). The upper electrode 20 contains, for example, borides of the above elements. The upper electrode 20 contains, for example, at least one material selected from a group consisting of hafnium, hafnium boride, magnesium aluminum boride, zirconium, zirconium boride, and titanium boride.

The intermediate electrode 30 includes a third portion 31 and a fourth portion 32. The third portion 31 is provided between the fourth portion 32 and the switching layer 40.

The third portion 31 contains, for example, at least one material selected from a group consisting of titanium, titanium nitride, carbon, carbon nitride, tungsten, tungsten carbide, and tungsten nitride.

The fourth portion 32 contains at least one element selected from hafnium (Hf), aluminum (Al), magnesium (Mg), zirconium (Zr), and titanium (Ti). The fourth portion 32 contains, for example, borides of the above elements. The fourth portion 32 contains, for example, at least one material selected from a group consisting of hafnium, hafnium boride, magnesium aluminum boride, zirconium, zirconium boride, and titanium boride.

In the memory device according to the third modification example of the first embodiment, since the first portion 11 of the lower electrode 10, the upper electrode 20, and the fourth portion 32 of the intermediate electrode 30 contain at least one element selected from hafnium (Hf), aluminum (Al), magnesium (Mg), zirconium (Zr), and titanium (Ti), degradation of the characteristics of the variable resistance element is suppressed. In addition, since the first portion 11 of the lower electrode 10, the upper electrode 20, and the fourth portion 32 of the intermediate electrode 30 are not in contact with the switching layer 40, desorption of oxygen (O) from the switching layer 40 is suppressed and accordingly, degradation of the characteristics of the switching element is suppressed.

As described above, according to the third modification example of the first embodiment, as in the first embodiment, it is possible to realize a switching element with excellent characteristics such as low half-select leakage current and high reliability.

According to the first embodiment and its modification examples, it is possible to realize a switching element with excellent characteristics such as low half-select leakage current and high reliability. Therefore, according to the first embodiment and its modification examples, it is possible to realize a memory device having switching elements with excellent characteristics.

### Second Embodiment

A memory device according to a second embodiment is different from the memory device according to the first embodiment in that the memory device according to the second embodiment is a resistive random access memory (ReRAM). Hereinafter, the description of a part of the content overlapping the first embodiment will be omitted.

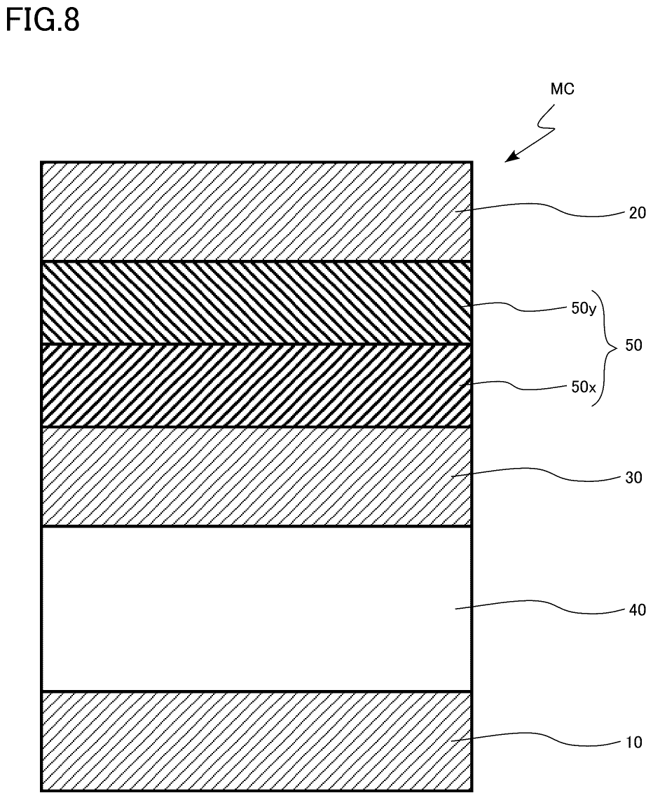

FIG. 8 is a schematic cross-sectional view of a memory cell in the memory device according to the second embodiment. FIG. 8 shows a cross section of one memory cell MC indicated by, for example, a dotted circle in the memory cell array 100 of FIG. 1.

As shown in FIG. 8, the memory cell MC includes a lower electrode 10, an upper electrode 20, an intermediate electrode 30, a switching layer 40, and a variable resistance layer 50. The variable resistance layer 50 includes a high resistance layer 50x and a low resistance layer 50y.

The lower electrode 10 is an example of the first conductive layer. The upper electrode 20 is an example of the second conductive layer. The intermediate electrode 30 is an example of the third conductive layer.

The lower electrode 10, the switching layer 40, and the intermediate electrode 30 form a switching element of the memory cell MC. The intermediate electrode 30, the variable resistance layer 50, and the upper electrode 20 form a variable resistance element of the memory cell MC.

The configuration of the switching layer 40 is similar to that in the memory device according to the first embodiment.

The variable resistance layer 50 includes the high resistance layer 50x and the low resistance layer 50y.

The high resistance layer 50x is, for example, a metal oxide. The high resistance layer 50x is, for example, an aluminum oxide, a hafnium oxide, a zirconium oxide, a tantalum oxide, or a niobium oxide.

The low resistance layer 50y is, for example, a metal oxide. The low resistance layer 50y is, for example, a titanium oxide, a niobium oxide, a tantalum oxide, or a tungsten oxide.

The variable resistance layer 50 has a function of storing data by resistance change. The variable resistance layer 50 has, for example, a characteristic that the electrical resistance changes with the application of a predetermined voltage.

By applying a voltage to the variable resistance layer 50, the variable resistance layer 50 changes from a high resistance state to a low resistance state or from a low resistance state to a high resistance state. By applying a voltage to the variable resistance layer 50, oxygen ions move between the high resistance layer 50x and the low resistance layer 50y, so that the amount of oxygen deficiency (the amount of oxygen vacancies) in the low resistance layer 50y changes. The electrical conductivity of the variable resistance layer 50 changes according to the amount of oxygen deficiency in the low resistance layer 50y. The low resistance layer 50y is a so-called vacancy modulated conductive oxide.

For example, the high resistance state is defined as data “1”, and the low resistance state is defined as data “0”. The memory cell MC can store 1-bit data of “0” and “1”.

As described above, according to the memory device according to the second embodiment, as in the first embodiment, it is possible to realize a switching element with excellent characteristics such as low half-select leakage current and high reliability. Therefore, according to the second embodiment, it is possible to realize a memory device having a switching element with excellent characteristics.

### Third Embodiment

A memory device according to a third embodiment includes a memory cell including a first conductive layer, a second conductive layer, and a memory layer provided between the first conductive layer and the second conductive layer. The memory layer contains an oxide of zinc (Zn) and a compound of the first element, which is at least one element selected from a group consisting of zinc (Zn), tin (Sn), gallium (Ga), indium (In), and bismuth (Bi), and the second element, which is at least one element selected from a group consisting of tellurium (Te), sulfur (S), selenium (Se), and antimony (Sb).

In addition, the memory device according to the third embodiment further includes a plurality of first wirings and a plurality of second wirings crossing the plurality of first wirings. In addition, the memory cell is provided in a region where one of the plurality of first wirings and one of the plurality of second wirings cross each other.

The memory device according to the third embodiment is different from the memory device according to the first and second embodiments in that the memory cell does not include a third conductive layer and a variable resistance layer and includes a structure similar to the switching layer in the first and second embodiments as a memory layer. Hereinafter, the description of a part of the content overlapping the first or second embodiment will be omitted.

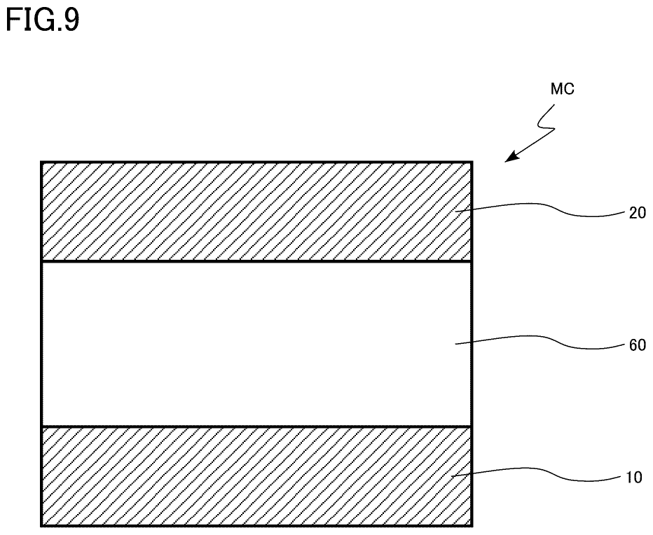

FIG. 9 is a schematic cross-sectional view of a memory cell in the memory device according to the third embodiment. FIG. 9 shows a cross section of one memory cell MC indicated by, for example, a dotted circle in the memory cell array 100 of FIG. 1.

As shown in FIG. 9, the memory cell MC includes a lower electrode 10, an upper electrode 20, and a memory layer 60.

The lower electrode 10 is an example of the first conductive layer. The upper electrode 20 is an example of the second conductive layer.

The lower electrode 10, the memory layer 60, and the upper electrode 20 form a memory element of the memory cell MC. The memory element of the memory cell MC has a switching function and an information storage function.

The memory layer 60 has a configuration similar to that of the switching layer 40 in the first and second embodiments. That is, the memory layer 60 contains an oxide of zinc (Zn) and a compound of the first element, which is at least one element selected from a group consisting of zinc (Zn), tin (Sn), gallium (Ga), indium (In), and bismuth (Bi), and the second element, which is at least one element selected from a group consisting of tellurium (Te), sulfur(S), selenium (Se), and antimony (Sb).

The memory layer 60 has a nonlinear current-voltage characteristic that a current increases abruptly at a specific threshold voltage. In addition, the memory layer 60 has a characteristic that the threshold voltage changes with the application of a predetermined voltage. The memory layer 60 has a characteristic that the electrical resistance changes with the application of a predetermined voltage. In the third embodiment, the high resistance state is a state in which the resistance of the memory layer 60 is relatively high at the read voltage. In addition, in the third embodiment, the low resistance state is a state in which the resistance of the memory layer 60 is relatively low at the read voltage.

The memory layer 60 has a function of suppressing an increase in half-select leakage current flowing through the half-selected cell. In addition, the memory layer 60 has a function of storing data by resistance change. The memory layer 60 is a single layer, and realizes the function of the switching layer 40 and the function of the variable resistance layer 50 in the first and second embodiments.

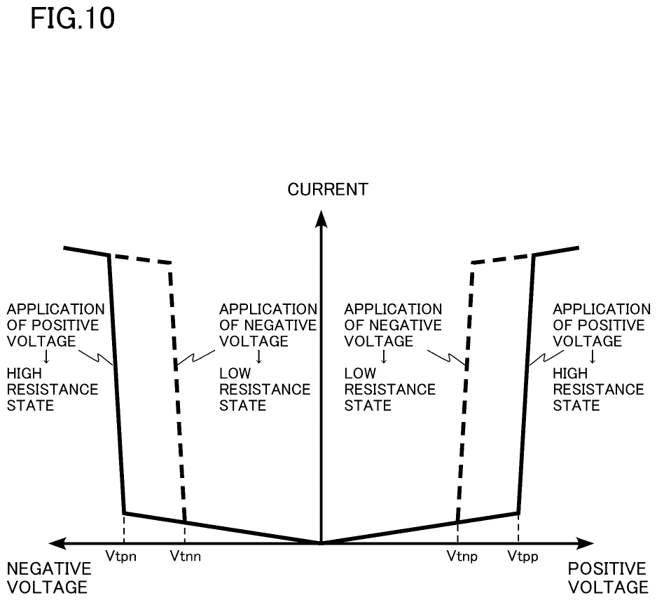

FIG. 10 is an explanatory diagram of the current-voltage characteristics of the memory element in the third embodiment. The horizontal axis indicates a voltage applied to the memory element, and the vertical axis indicates a current flowing through the memory element. In FIG. 10, the horizontal axis indicates a voltage applied to the upper electrode 20 with the electric potential of the lower electrode 10 as a reference. FIG. 10 shows the current-voltage characteristics of the memory layer 60 in the third embodiment. FIG. 10 shows the current-voltage characteristics of the memory cell MC in the third embodiment.

The memory element in the third embodiment shows different current-voltage characteristics when a predetermined positive voltage is applied to the upper electrode 20 and when a predetermined negative voltage is applied to the upper electrode 20. In FIG. 10, the solid line indicates the current-voltage characteristics when a predetermined positive voltage is applied to the upper electrode 20, and the dotted line indicates the current-voltage characteristics when a predetermined negative voltage is applied to the upper electrode 20.

When a predetermined positive voltage is applied to the upper electrode 20, the current increases abruptly at a first positive voltage side threshold voltage Vtpp on the positive voltage side. In addition, when a predetermined positive voltage is applied to the upper electrode 20, the current increases abruptly at a first negative voltage side threshold voltage Vtpn on the negative voltage side.

On the other hand, when a predetermined negative voltage is applied to the upper electrode 20, the current increases abruptly at a second positive voltage side threshold voltage Vtnp on the positive voltage side. In addition, when a predetermined negative voltage is applied to the upper electrode 20, the current increases abruptly at a second negative voltage side threshold voltage Vtnn on the negative voltage side.

The first positive voltage side threshold voltage Vtpp is higher than the second positive voltage side threshold voltage Vtnp. In addition, the first negative voltage side threshold voltage Vtpn is lower than the second negative voltage side threshold voltage Vtnn.

The memory element in the third embodiment can have a high resistance state and a low resistance state on both the positive voltage side and the negative voltage side. When a predetermined positive voltage is applied to the upper electrode 20, a high resistance state is realized on both the positive voltage side and the negative voltage side. On the other hand, when a predetermined negative voltage is applied to the upper electrode 20, a low resistance state is realized on both the positive voltage side and the negative voltage side. Hereinafter, the high resistance state will be defined as data “1”, and the low resistance state will be defined as data “0”. The memory cell MC can store 1-bit data of “0” and “1”.

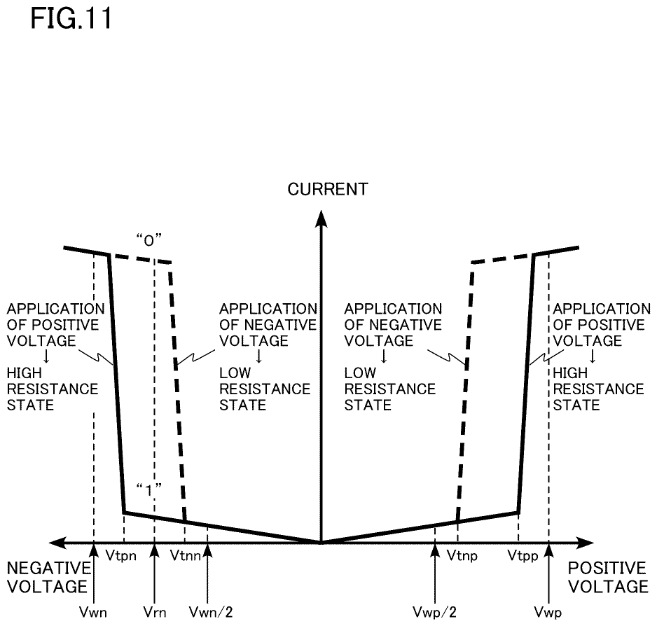

FIG. 11 is an explanatory diagram of a first operation example of the memory operation of the memory device according to the third embodiment. FIG. 11 shows a positive side write voltage Vwp, half (Vwp/2) the positive side write voltage Vwp, a negative side write voltage Vwn, half (Vwn/2) the negative side write voltage Vwn, and a negative side read voltage Vrn when performing a memory operation.

In the first operation example, the high resistance state and the low resistance state on the negative voltage side are used for the memory operation. In the first operation example, the negative side read voltage Vrn is used as a read voltage.

When writing data “1” to the selected cell, the positive side write voltage Vwp is applied to the upper electrode 20. The positive side write voltage Vwp is a voltage higher than the first positive voltage side threshold voltage Vtpp. By applying the positive side write voltage Vwp to the upper electrode 20, a high resistance state is realized on the negative voltage side, and data “1” is written to the selected cell.

When writing data “0” to the selected cell, the negative side write voltage Vwn is applied to the upper electrode 20. The negative side write voltage Vwn is a voltage lower than the first negative voltage side threshold voltage Vtpn. By applying the negative side write voltage Vwn to the upper electrode 20, a low resistance state is realized on the negative voltage side, and data “0” is written to the selected cell.

In the first operation example, when writing data “1” to the selected cell, assuming that the data stored in the selected cell is data “0”, a current flows if the positive side write voltage Vwp is higher than the second positive voltage side threshold voltage Vtnp even if the positive side write voltage Vwp is lower than the first positive voltage side threshold voltage Vtpp. For this reason, data “1” may be written. Therefore, for example, by setting the positive side write voltage Vwp to a voltage between the second positive voltage side threshold voltage Vtnp and the first positive voltage side threshold voltage Vtpp, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the second positive voltage side threshold voltage Vtnp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory element also functions as a switching element.

When reading data from the selected cell, the negative side read voltage Vrn is applied to the selected cell. The data of the selected cell can be determined by detecting a current change or an electric potential change caused by the difference between a current that flows when data is “1” and a current that flows when data is “0”.

In addition, in the case of the first operation example, regardless of whether the data of the selected cell is data “1” or data “0”, the application of the negative side read voltage Vrn does not destroy the data. In other words, in the case of the first operation example, non-destructive reading is possible regardless of whether the data of the selected cell is data “1” or data “0”.

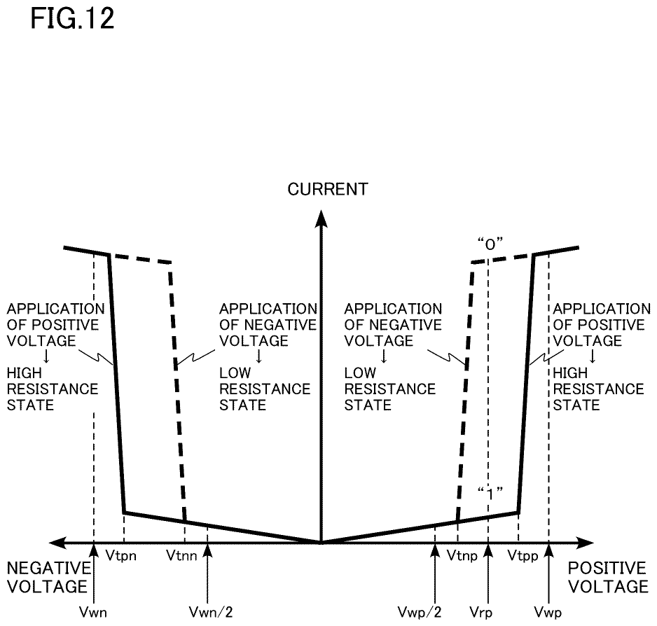

FIG. 12 is an explanatory diagram of a second operation example of the memory operation of the memory device according to the third embodiment. FIG. 12 shows a positive side write voltage Vwp, half (Vwp/2) the positive side write voltage Vwp, a negative side write voltage Vwn, half (Vwn/2) the negative side write voltage Vwn, and a positive side read voltage Vrp when performing a memory operation.

In the second operation example, the high resistance state and the low resistance state on the positive voltage side are used for the memory operation. In the second operation example, the positive side read voltage Vrp is used as a read voltage.

When writing data “1” to the selected cell, the positive side write voltage Vwp is applied to the upper electrode 20. The positive side write voltage Vwp is a voltage higher than the first positive voltage side threshold voltage Vtpp. By applying the positive side write voltage Vwp to the upper electrode 20, a high resistance state is realized on the positive voltage side, and data “1” is written to the selected cell.

When writing data “0” to the selected cell, the negative side write voltage Vwn is applied to the upper electrode 20. The negative side write voltage Vwn is a voltage lower than the first negative voltage side threshold voltage Vtpn. By applying the negative side write voltage Vwn to the upper electrode 20, a low resistance state is realized on the positive voltage side, and data “0” is written to the selected cell.

In the second operation example, when writing data “1” to the selected cell, assuming that the data stored in the selected cell is data “0”, a current flows if the positive side write voltage Vwp is higher than the second positive voltage side threshold voltage Vtnp even if the positive side write voltage Vwp is lower than the first positive voltage side threshold voltage Vtpp. For this reason, data “1” may be written. Therefore, for example, by setting the positive side write voltage Vwp to a voltage between the second positive voltage side threshold voltage Vtnp and the first positive voltage side threshold voltage Vtpp, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the second positive voltage side threshold voltage Vtnp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory element also functions as a switching element.

When reading data from the selected cell, the positive side read voltage Vrp is applied to the selected cell. The data of the selected cell can be determined by detecting a current change or an electric potential change caused by the difference between a current that flows when data is “1” and a current that flows when data is “0”.

In addition, in the case of the second operation example, when the data of the selected cell is data “1”, the application of the positive side read voltage Vrp does not destroy the data. In other words, in the case of the second operation example, non-destructive reading is possible if the data of the selected cell is data “1”.

On the other hand, when the data of the selected cell is data “0”, the application of the positive side read voltage Vrp higher than the second positive voltage side threshold voltage Vtnp may cause a current to flow. As a result, the data of the selected cell may change to data “1”. In other words, in the case of the second operation example, when the data of the selected cell is data “0”, there is a possibility of destructive reading. Therefore, when the data of the selected cell is data “0”, it may be necessary to rewrite the data “0” in order to maintain the data of the selected cell after reading the data of the selected cell.

### First Modification Example

A memory device according to a first modification example of the third embodiment is different from the memory device according to the third embodiment in that the current-voltage characteristics of the memory elements are different.

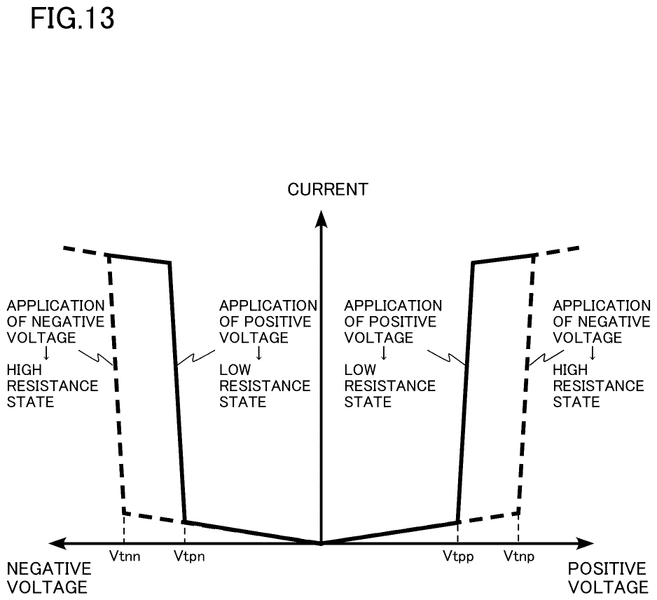

FIG. 13 is an explanatory diagram of the current-voltage characteristics of a memory element in the first modification example of the third embodiment. The horizontal axis indicates a voltage applied to the memory element, and the vertical axis indicates a current flowing through the memory element. In FIG. 13, the horizontal axis indicates a voltage applied to the upper electrode 20 with the electric potential of the lower electrode 10 as a reference. FIG. 13 shows the current-voltage characteristics of the memory layer 60 in the first modification example of the third embodiment. FIG. 13 shows the current-voltage characteristics of the memory cell MC in the first modification example of the third embodiment.

The memory element in the first modification example of the third embodiment shows different current-voltage characteristics when a predetermined positive voltage is applied to the upper electrode 20 and when a predetermined negative voltage is applied to the upper electrode 20. In FIG. 13, the solid line indicates the current-voltage characteristics when a predetermined positive voltage is applied to the upper electrode 20, and the dotted line indicates the current-voltage characteristics when a predetermined negative voltage is applied to the upper electrode 20.

When a predetermined positive voltage is applied to the upper electrode 20, the current increases abruptly at a first positive voltage side threshold voltage Vtpp on the positive voltage side. In addition, when a predetermined positive voltage is applied to the upper electrode 20, the current increases abruptly at a first negative voltage side threshold voltage Vtpn on the negative voltage side.

On the other hand, when a predetermined negative voltage is applied to the upper electrode 20, the current increases abruptly at a second positive voltage side threshold voltage Vtnp on the positive voltage side. In addition, when a predetermined negative voltage is applied to the upper electrode 20, the current increases abruptly at a second negative voltage side threshold voltage Vtnn on the negative voltage side.

The first positive voltage side threshold voltage Vtpp is lower than the second positive voltage side threshold voltage Vtnp. In addition, the first negative voltage side threshold voltage Vtpn is higher than the second negative voltage side threshold voltage Vtnn.

The memory element in the first modification example of the third embodiment can have a high resistance state and a low resistance state on both the positive voltage side and the negative voltage side. When a predetermined positive voltage is applied to the upper electrode 20, a low resistance state is realized on both the positive voltage side and the negative voltage side. On the other hand, when a predetermined negative voltage is applied to the upper electrode 20, a high resistance state is realized on both the positive voltage side and the negative voltage side. Hereinafter, the high resistance state will be defined as data “1”, and the low resistance state will be defined as data “0”. The memory cell MC can store 1-bit data of “0” and “1”.

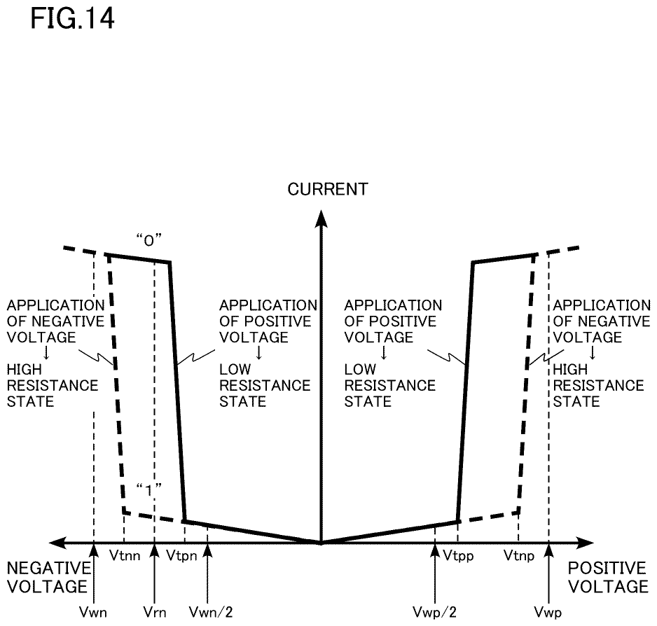

FIG. 14 is an explanatory diagram of a third operation example of the memory operation of the memory device according to the first modification example of the third embodiment. FIG. 14 shows a positive side write voltage Vwp, half (Vwp/2) the positive side write voltage Vwp, a negative side write voltage Vwn, half (Vwn/2) the negative side write voltage Vwn, and a negative side read voltage Vrn when performing a memory operation.

In the third operation example, the high resistance state and the low resistance state on the negative voltage side are used for the memory operation. In the third operation example, the negative side read voltage Vrn is used as a read voltage.

When writing data “1” to the selected cell, the negative side write voltage Vwn is applied to the upper electrode 20. The negative side write voltage Vwn is a voltage lower than the second negative voltage side threshold voltage Vtnn. By applying the negative side write voltage Vwn to the upper electrode 20, a high resistance state is realized on the negative voltage side, and data “1” is written to the selected cell.

When writing data “0” to the selected cell, the positive side write voltage Vwp is applied to the upper electrode 20. The positive side write voltage Vwp is a voltage higher than the second positive voltage side threshold voltage Vtnp. By applying the positive side write voltage Vwp to the upper electrode 20, a low resistance state is realized on the negative voltage side, and data “0” is written to the selected cell.

In the third operation example, when writing data “1” to the selected cell, assuming that the data stored in the selected cell is data “0”, a current flows if the negative side write voltage Vwn is lower than the first negative voltage side threshold voltage Vtpn even if the negative side write voltage Vwn is higher than the second negative voltage side threshold voltage Vtnn. For this reason, data “1” may be written. Therefore, for example, by setting the negative side write voltage Vwn to a voltage between the second negative voltage side threshold voltage Vtnn and the first negative voltage side threshold voltage Vtpn, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the first negative voltage side threshold voltage Vtpn.

Therefore, even when the half-selected cell is in the low resistance state, the half-select leakage current flowing through the half-selected cell can be suppressed. As a result, the memory element also functions as a switching element.

When reading data from the selected cell, the negative side read voltage Vrn is applied to the selected cell. The data of the selected cell can be determined by detecting a current change or an electric potential change caused by the difference between a current that flows when data is “1” and a current that flows when data is “0”.

In addition, in the case of the third operation example, when the data of the selected cell is data “1”, the application of the negative side read voltage Vrn does not destroy the data. In other words, in the case of the third operation example, non-destructive reading is possible if the data of the selected cell is data “1”.

On the other hand, when the data of the selected cell is data “0”, the application of the negative side read voltage Vrn lower than the first negative voltage side threshold voltage Vtpn may cause a current to flow. As a result, the data of the selected cell may change to data “1”. In other words, in the case of the third operation example, when the data of the selected cell is data “0”, there is a possibility of destructive reading. Therefore, when the data of the selected cell is data “0”, it may be necessary to rewrite the data “0” in order to maintain the data of the selected cell after reading the data of the selected cell.

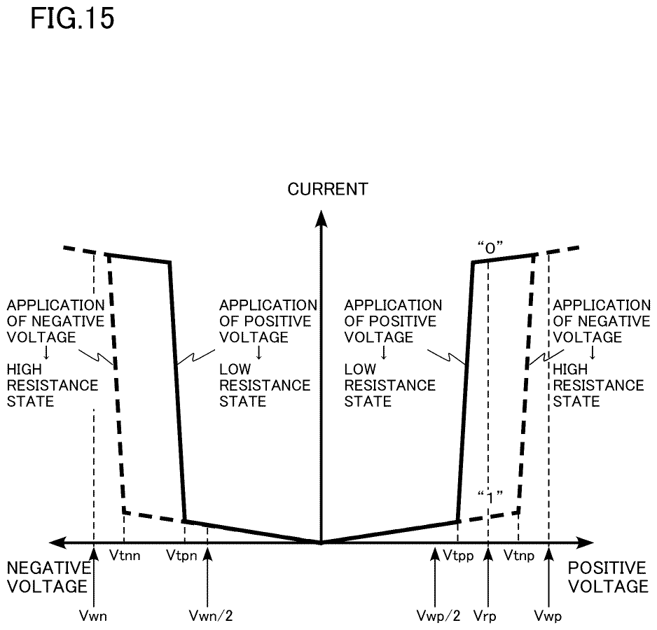

FIG. 15 is an explanatory diagram of a fourth operation example of the memory operation of the memory device according to the first modification example of the third embodiment. FIG. 15 shows a positive side write voltage Vwp, half (Vwp/2) the positive side write voltage Vwp, a negative side write voltage Vwn, half (Vwn/2) the negative side write voltage Vwn, and a positive side read voltage Vrp when performing a memory operation.

In the fourth operation example, the high resistance state and the low resistance state on the positive voltage side are used for the memory operation. In the fourth operation example, the positive side read voltage Vrp is used as a read voltage.

When writing data “1” to the selected cell, the negative side write voltage Vwn is applied to the upper electrode 20. The negative side write voltage Vwn is a voltage lower than the second negative voltage side threshold voltage Vtnn. By applying the negative side write voltage Vwn to the upper electrode 20, a high resistance state is realized on the positive voltage side, and data “1” is written to the selected cell.

When writing data “0” to the selected cell, the positive side write voltage Vwp is applied to the upper electrode 20. The positive side write voltage Vwp is a voltage higher than the second positive voltage side threshold voltage Vtnp. By applying the positive side write voltage Vwp to the upper electrode 20, a low resistance state is realized on the positive voltage side, and data “0” is written to the selected cell.

In the fourth operation example, when writing data “1” to the selected cell, assuming that the data stored in the selected cell is data “0”, a current flows if the negative side write voltage Vwn is lower than the first negative voltage side threshold voltage Vtpn even if the negative side write voltage Vwn is higher than the second negative voltage side threshold voltage Vtnn. For this reason, data “1” may be written. Therefore, for example, by setting the negative side write voltage Vwn to a voltage between the second negative voltage side threshold voltage Vtnn and the first negative voltage side threshold voltage Vtpn, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the first negative voltage side threshold voltage Vtpn.

Therefore, even when the half-selected cell is in the low resistance state, the half-select leakage current flowing through the half-selected cell can be suppressed. As a result, the memory element also functions as a switching element.

When reading data from the selected cell, the positive side read voltage Vrp is applied to the selected cell. The data of the selected cell can be determined by detecting a current change or an electric potential change caused by the difference between a current that flows when data is “1” and a current that flows when data is “0”.

In addition, in the case of the fourth operation example, regardless of whether the data of the selected cell is data “1” or data “0”, the application of the positive side read voltage Vrp does not destroy the data. In other words, in the case of the fourth operation example, non-destructive reading is possible regardless of whether the data of the selected cell is data “1” or data “0”.

### Second Modification Example

A memory device according to a second modification example of the third embodiment is different from the memory device according to the third embodiment in that the current-voltage characteristics of the memory elements are different.

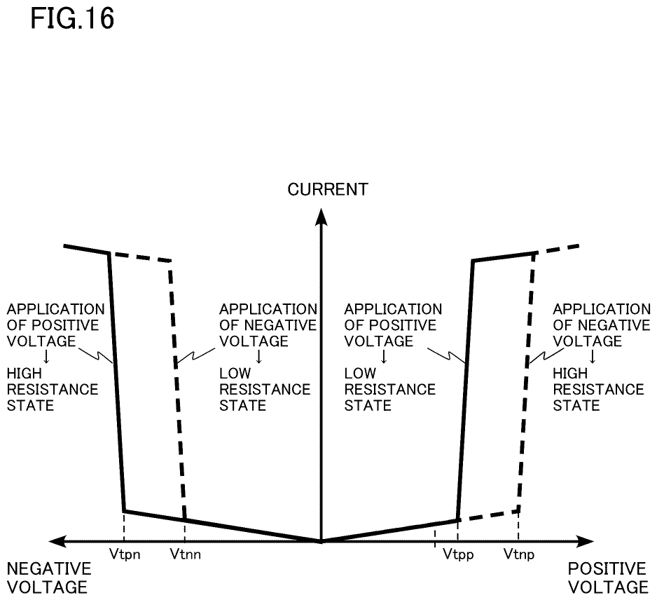

FIG. 16 is an explanatory diagram of the current-voltage characteristics of the memory element in the second modification example of the third embodiment. The horizontal axis indicates a voltage applied to the memory element, and the vertical axis indicates a current flowing through the memory element. In FIG. 16, the horizontal axis indicates a voltage applied to the upper electrode 20 with the electric potential of the lower electrode 10 as a reference. FIG. 16 shows the current-voltage characteristics of the memory layer 60 in the second modification example of the third embodiment. FIG. 16 shows the current-voltage characteristics of the memory cell MC in the second modification example of the third embodiment.

The memory element in the second modification example of the third embodiment shows different current-voltage characteristics when a predetermined positive voltage is applied to the upper electrode 20 and when a predetermined negative voltage is applied to the upper electrode 20. In FIG. 16, the solid line indicates the current-voltage characteristics when a predetermined positive voltage is applied to the upper electrode 20, and the dotted line indicates the current-voltage characteristics when a predetermined negative voltage is applied to the upper electrode 20.

When a predetermined positive voltage is applied to the upper electrode 20, the current increases abruptly at a first positive voltage side threshold voltage Vtpp on the positive voltage side. In addition, when a predetermined positive voltage is applied to the upper electrode 20, the current increases abruptly at a first negative voltage side threshold voltage Vtpn on the negative voltage side.

On the other hand, when a predetermined negative voltage is applied to the upper electrode 20, the current increases abruptly at a second positive voltage side threshold voltage Vtnp on the positive voltage side. In addition, when a predetermined negative voltage is applied to the upper electrode 20, the current increases abruptly at a second negative voltage side threshold voltage Vtnn on the negative voltage side.

The first positive voltage side threshold voltage Vtpp is lower than the second positive voltage side threshold voltage Vtnp. In addition, the first negative voltage side threshold voltage Vtpn is lower than the second negative voltage side threshold voltage Vtnn.

The memory element in the second modification example of the third embodiment can have a high resistance state and a low resistance state on both the positive voltage side and the negative voltage side. When a predetermined positive voltage is applied to the upper electrode 20, a low resistance state is realized on the positive voltage side and a high resistance state is realized on the negative voltage side. On the other hand, when a predetermined negative voltage is applied to the upper electrode 20, a high resistance state is realized on the positive voltage side and a low resistance state is realized on the negative voltage side. Hereinafter, the high resistance state will be defined as data “1”, and the low resistance state will be defined as data “0”. The memory cell MC can store 1-bit data of “0” and “1”.

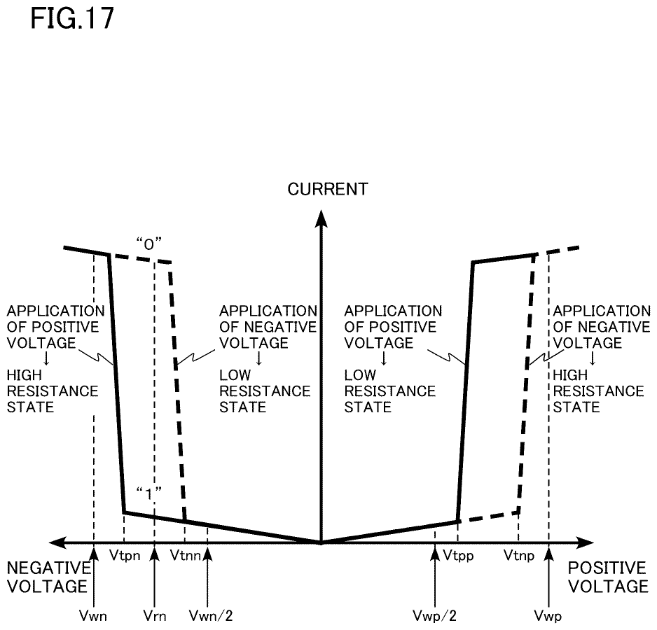

FIG. 17 is an explanatory diagram of a fifth operation example of the memory operation of the memory device according to the second modification example of the third embodiment. FIG. 17 shows a positive side write voltage Vwp, half (Vwp/2) the positive side write voltage Vwp, a negative side write voltage Vwn, half (Vwn/2) the negative side write voltage Vwn, and a negative side read voltage Vrn when performing a memory operation.

In the fifth operation example, the high resistance state and the low resistance state on the negative voltage side are used for the memory operation. In the fifth operation example, the negative side read voltage Vrn is used as a read voltage.

When writing data “1” to the selected cell, the positive side write voltage Vwp is applied to the upper electrode 20. The positive side write voltage Vwp is a voltage higher than the second positive voltage side threshold voltage Vtnp. By applying the positive side write voltage Vwp to the upper electrode 20, a high resistance state is realized on the negative voltage side, and data “1” is written to the selected cell.

When writing data “0” to the selected cell, the negative side write voltage Vwn is applied to the upper electrode 20. The negative side write voltage Vwn is a voltage lower than the first negative voltage side threshold voltage Vtpn. By applying the negative side write voltage Vwn to the upper electrode 20, a low resistance state is realized on the negative voltage side, and data “0” is written to the selected cell.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory element also functions as a switching element.

When reading data from the selected cell, the negative side read voltage Vrn is applied to the selected cell. The data of the selected cell can be determined by detecting a current change or an electric potential change caused by the difference between a current that flows when data is “1” and a current that flows when data is “0”.

In addition, in the case of the fifth operation example, regardless of whether the data of the selected cell is data “1” or data “0”, the application of the negative side read voltage Vrn does not destroy the data. In other words, in the case of the fifth operation example, non-destructive reading is possible regardless of whether the data of the selected cell is data “1” or data “0”.

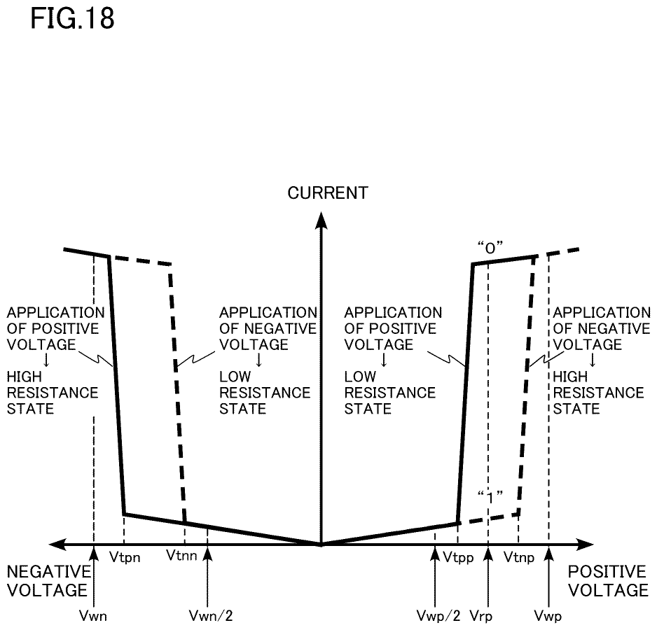

FIG. 18 is an explanatory diagram of a sixth operation example of the memory operation of the memory device according to the second modification example of the third embodiment. FIG. 18 shows a positive side write voltage Vwp, half (Vwp/2) the positive side write voltage Vwp, a negative side write voltage Vwn, half (Vwn/2) the negative side write voltage Vwn, and a positive side read voltage Vrp when performing a memory operation.

In the sixth operation example, the high resistance state and the low resistance state on the positive voltage side are used for the memory operation. In the sixth operation example, the positive side read voltage Vrp is used as a read voltage.

When writing data “1” to the selected cell, the negative side write voltage Vwn is applied to the upper electrode 20. The negative side write voltage Vwn is a voltage lower than the first negative voltage side threshold voltage Vtpn. By applying the negative side write voltage Vwn to the upper electrode 20, a high resistance state is realized on the positive voltage side, and data “1” is written to the selected cell.

When writing data “0” to the selected cell, the positive side write voltage Vwp is applied to the upper electrode 20. The positive side write voltage Vwp is a voltage higher than the second positive voltage side threshold voltage Vtnp. By applying the positive side write voltage Vwp to the upper electrode 20, a low resistance state is realized on the positive voltage side, and data “0” is written to the selected cell.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the first positive voltage side threshold voltage Vtpp. In addition, the voltage Vwn/2 is higher than the second negative voltage side threshold voltage Vtnn.

Therefore, even when the half-selected cell is in the low resistance state, the half-select leakage current flowing through the half-selected cell can be suppressed. As a result, the memory element also functions as a switching element.

When reading data from the selected cell, the positive side read voltage Vrp is applied to the selected cell. The data of the selected cell can be determined by detecting a current change or an electric potential change caused by the difference between a current that flows when data is “1” and a current that flows when data is “0”.

In addition, in the case of the sixth operation example, regardless of whether the data of the selected cell is data “1” or data “0”, the application of the positive side read voltage Vrp does not destroy the data. In other words, in the case of the sixth operation example, non-destructive reading is possible regardless of whether the data of the selected cell is data “1” or data “0”.

### Third Modification Example

A memory device according to a third modification example of the third embodiment is different from the memory device according to the third embodiment in that the current-voltage characteristics of the memory elements are different.

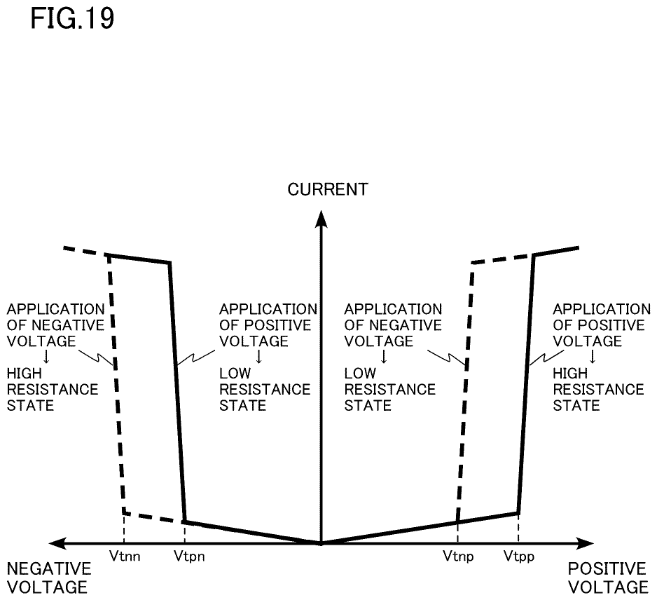

FIG. 19 is an explanatory diagram of the current-voltage characteristics of a memory element in the third modification example of the third embodiment. The horizontal axis indicates a voltage applied to the memory element, and the vertical axis indicates a current flowing through the memory element. In FIG. 19, the horizontal axis indicates a voltage applied to the upper electrode 20 with the electric potential of the lower electrode 10 as a reference. FIG. 19 shows the current-voltage characteristics of the memory layer 60 in the third modification example of the third embodiment. FIG. 19 shows the current-voltage characteristics of the memory cell MC in the third modification example of the third embodiment.

The memory element in the third modification example of the third embodiment shows different current-voltage characteristics when a predetermined positive voltage is applied to the upper electrode 20 and when a predetermined negative voltage is applied to the upper electrode 20. In FIG. 19, the solid line indicates the current-voltage characteristics when a predetermined positive voltage is applied to the upper electrode 20, and the dotted line indicates the current-voltage characteristics when a predetermined negative voltage is applied to the upper electrode 20.

When a predetermined positive voltage is applied to the upper electrode 20, the current increases abruptly at a first positive voltage side threshold voltage Vtpp on the positive voltage side. In addition, when a predetermined positive voltage is applied to the upper electrode 20, the current increases abruptly at a first negative voltage side threshold voltage Vtpn on the negative voltage side.

On the other hand, when a predetermined negative voltage is applied to the upper electrode 20, the current increases abruptly at a second positive voltage side threshold voltage Vtnp on the positive voltage side. In addition, when a predetermined negative voltage is applied to the upper electrode 20, the current increases abruptly at a second negative voltage side threshold voltage Vtnn on the negative voltage side.

The first positive voltage side threshold voltage Vtpp is higher than the second positive voltage side threshold voltage Vtnp. In addition, the first negative voltage side threshold voltage Vtpn is higher than the second negative voltage side threshold voltage Vtnn.

The memory element according to the third modification example of the third embodiment can have a high resistance state and a low resistance state on both the positive voltage side and the negative voltage side. When a predetermined positive voltage is applied to the upper electrode 20, a high resistance state is realized on the positive voltage side and a low resistance state is realized on the negative voltage side. On the other hand, when a predetermined negative voltage is applied to the upper electrode 20, a low resistance state is realized on the positive voltage side and a high resistance state is realized on the negative voltage side. Hereinafter, the high resistance state will be defined as data “1”, and the low resistance state will be defined as data “0”. The memory cell MC can store 1-bit data of “0” and “1”.

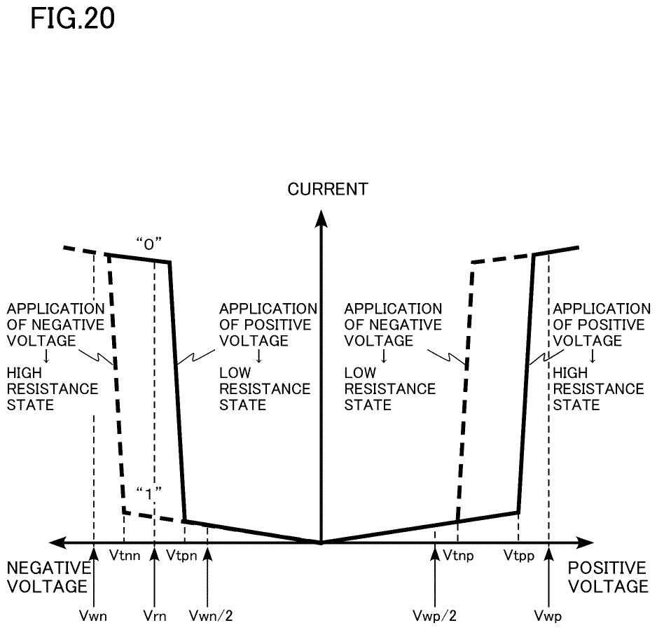

FIG. 20 is an explanatory diagram of a seventh operation example of the memory operation of the memory device according to the third modification example of the third embodiment. FIG. 20 shows a positive side write voltage Vwp, half (Vwp/2) the positive side write voltage Vwp, a negative side write voltage Vwn, half (Vwn/2) the negative side write voltage Vwn, and a negative side read voltage Vrn when performing a memory operation.

In the seventh operation example, the high resistance state and the low resistance state on the negative voltage side are used for the memory operation. In the seventh operation example, the negative side read voltage Vrn is used as a read voltage.

When writing data “1” to the selected cell, the negative side write voltage Vwn is applied to the upper electrode 20. The negative side write voltage Vwn is a voltage lower than the second negative voltage side threshold voltage Vtnn. By applying the negative side write voltage Vwn to the upper electrode 20, a high resistance state is realized on the negative voltage side, and data “1” is written to the selected cell.

When writing data “0” to the selected cell, the positive side write voltage Vwp is applied to the upper electrode 20. The positive side write voltage Vwp is a voltage higher than the first positive voltage side threshold voltage Vtpp. By applying the positive side write voltage Vwp to the upper electrode 20, a low resistance state is realized on the negative voltage side, and data “0” is written to the selected cell.

In the seventh operation example, when writing data “1” to the selected cell, assuming that the data stored in the selected cell is data “0”, a current flows if the negative side write voltage Vwn is lower than the first negative voltage side threshold voltage Vtpn even if the negative side write voltage Vwn is higher than the second negative voltage side threshold voltage Vtnn. For this reason, data “1” may be written. Therefore, for example, by setting the negative side write voltage Vwn to a voltage between the second negative voltage side threshold voltage Vtnn and the first negative voltage side threshold voltage Vtpn, it is possible to reduce the power consumption of the memory device or increase the reliability.

In addition, in the seventh operation example, when writing data “0” to the selected cell, assuming that the data stored in the selected cell is data “1”, a current flows if the positive side write voltage Vwp is higher than the second positive voltage side threshold voltage Vtnp even if the positive side write voltage Vwp is lower than the first positive voltage side threshold voltage Vtpp. For this reason, data “0” may be written. Therefore, for example, by setting the positive side write voltage Vwp to a voltage between the second positive voltage side threshold voltage Vtnp and the first positive voltage side threshold voltage Vtpp, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the second positive voltage side threshold voltage Vtnp. In addition, the voltage Vwn/2 is higher than the first negative voltage side threshold voltage Vtpn.

Therefore, even when the half-selected cell is in the low resistance state, the half-select leakage current flowing through the half-selected cell can be suppressed. As a result, the memory element also functions as a switching element.

When reading data from the selected cell, the negative side read voltage Vrn is applied to the selected cell. The data of the selected cell can be determined by detecting a current change or an electric potential change caused by the difference between a current that flows when data is “1” and a current that flows when data is “0”.

In addition, in the case of the seventh operation example, when the data of the selected cell is data “1”, the application of the negative side read voltage Vrn does not destroy the data. In other words, in the case of the seventh operation example, non-destructive reading is possible if the data of the selected cell is data “1”.

On the other hand, when the data of the selected cell is data “0”, the application of the negative side read voltage Vrn lower than the first negative voltage side threshold voltage Vtpn may cause a current to flow. As a result, the data of the selected cell may change to data “1”. In other words, in the case of the seventh operation example, when the data of the selected cell is data “0”, there is a possibility of destructive reading. Therefore, when the data of the selected cell is data “0”, it may be necessary to rewrite the data “0” in order to maintain the data of the selected cell after reading the data of the selected cell.

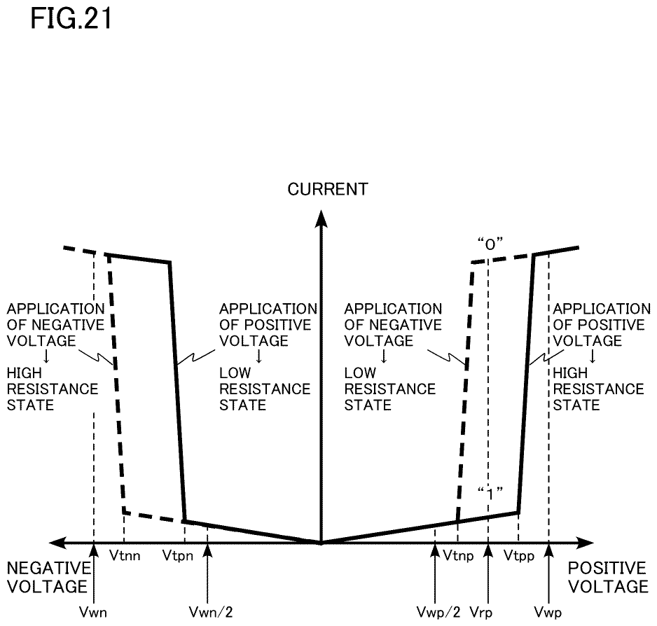

FIG. 21 is an explanatory diagram of an eighth operation example of the memory operation of the memory device according to the third modification example of the third embodiment. FIG. 21 shows a positive side write voltage Vwp, half (Vwp/2) the positive side write voltage Vwp, a negative side write voltage Vwn, half (Vwn/2) the negative side write voltage Vwn, and a positive side read voltage Vrp when performing a memory operation.

In the eighth operation example, the high resistance state and the low resistance state on the positive voltage side are used for the memory operation. In the eighth operation example, the positive side read voltage Vrp is used as a read voltage.

When writing data “1” to the selected cell, the positive side write voltage Vwp is applied to the upper electrode 20. The positive side write voltage Vwp is a voltage higher than the first positive voltage side threshold voltage Vtpp. By applying the positive side write voltage Vwp to the upper electrode 20, a high resistance state is realized on the positive voltage side, and data “1” is written to the selected cell.

When writing data “0” to the selected cell, the negative side write voltage Vwn is applied to the upper electrode 20. The negative side write voltage Vwn is a voltage lower than the second negative voltage side threshold voltage Vtnn. By applying the negative side write voltage Vwn to the upper electrode 20, a low resistance state is realized on the positive voltage side, and data “0” is written to the selected cell.

In the eighth operation example, when writing data “1” to the selected cell, assuming that the data stored in the selected cell is data “0”, a current flows if the positive side write voltage Vwp is higher than the second positive voltage side threshold voltage Vtnp even if the positive side write voltage Vwp is lower than the first positive voltage side threshold voltage Vtpp. For this reason, data “1” may be written. Therefore, for example, by setting the positive side write voltage Vwp to a voltage between the second positive voltage side threshold voltage Vtnp and the first positive voltage side threshold voltage Vtpp, it is possible to reduce the power consumption of the memory device or increase the reliability.

In addition, in the eighth operation example, when writing data “0” to the selected cell, assuming that the data stored in the selected cell is data “1”, a current flows if the negative side write voltage Vwn is lower than the first negative voltage side threshold voltage Vtpn even if the negative side write voltage Vwn is higher than the second negative voltage side threshold voltage Vtnn. For this reason, data “0” may be written. Therefore, for example, by setting the negative side write voltage Vwn to a voltage between the second negative voltage side threshold voltage Vtnn and the first negative voltage side threshold voltage Vtpn, it is possible to reduce the power consumption of the memory device or increase the reliability.

In addition, when the positive side write voltage Vwp is applied to the selected cell, the voltage Vwp/2 is applied to the half-selected cell. In addition, when the negative side write voltage Vwn is applied to the selected cell, the voltage Vwn/2 is applied to the half-selected cell. The voltage Vwp/2 is lower than the second positive voltage side threshold voltage Vtnp. In addition, the voltage Vwn/2 is higher than the first negative voltage side threshold voltage Vtpn.

Therefore, even when the half-selected cell is in the low resistance state, the half-select leakage current flowing through the half-selected cell can be suppressed. As a result, the memory element also functions as a switching element.

When reading data from the selected cell, the positive side read voltage Vrp is applied to the selected cell. The data of the selected cell can be determined by detecting a current change or an electric potential change caused by the difference between a current that flows when data is “1” and a current that flows when data is “0”.

In addition, in the case of the eighth operation example, when the data of the selected cell is data “1”, the application of the positive side read voltage Vrp does not destroy the data. In other words, in the case of the eighth operation example, non-destructive reading is possible if the data of the selected cell is data “1”.

On the other hand, when the data of the selected cell is data “0”, the application of the positive side read voltage Vrp higher than the second positive voltage side threshold voltage Vtnp may cause a current to flow. As a result, the data of the selected cell may change to data “1”. In other words, in the case of the eighth operation example, when the data of the selected cell is data “0”, there is a possibility of destructive reading. Therefore, when the data of the selected cell is data “0”, it may be necessary to rewrite the data “0” in order to maintain the data of the selected cell after reading the data of the selected cell.

In the memory devices according to the third embodiment and its modification examples, the memory element of the memory cell MC has a switching function and an information storage function. The memory layer 60 is a single layer, and realizes the function of the switching layer 40 and the function of the variable resistance layer 50 in the first and second embodiments. Since the memory layer 60 in the third embodiment is a single layer and has a switching function and a memory function, the structure of the memory cell MC can be made very simple.

In addition, the memory layer 60 of the memory device according to the third embodiment and its modification examples has the same configuration as the switching layer 40 in the first and second embodiments. Therefore, according to the third embodiment and its modification examples, as in the first and second embodiments, it is possible to realize a memory device with excellent switching characteristics such as low half-select leakage current and high reliability.

In addition, the plurality of current-voltage characteristics of the memory elements shown in the third embodiment and its modification examples can be realized, for example, by adopting the memory layer 60 having an appropriate chemical composition.

Although the magnetoresistive memory has been described as an example of the two-terminal memory device in the first embodiment and the resistive random access memory has been described as an example of the memory device in the second embodiment, embodiments can be applied to other two-terminal memory devices. For example, embodiments can be applied to a phase change memory (PCM) or a ferroelectric random access memory (FeRAM).

While certain embodiments have been described, these embodiments have been presented by way of example only, and are not intended to limit the scope of the inventions. Indeed, the memory device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A memory device, comprising:
a memory cell including a first conductive layer, a second conductive layer, a third conductive layer provided between the first conductive layer and the second conductive layer, a switching layer provided between the first conductive layer and the third conductive layer, and a variable resistance layer provided between the third conductive layer and the second conductive layer,
wherein the switching layer contains an oxide of zinc (Zn) and a compound of a first element and a second element, the first element being at least one element selected from a group consisting of zinc (Zn), tin (Sn), gallium (Ga), indium (In), and bismuth (Bi) and the second element being at least one element selected from a group consisting of tellurium (Te), sulfur(S), selenium (Se), and antimony (Sb).

2. The memory device according to claim 1,
wherein the switching layer further contains an oxide of a third element, the third element being at least one element selected from a group consisting of zirconium (Zr), silicon (Si), hafnium (Hf), and aluminum (Al).

3. The memory device according to claim 2,
wherein an atomic concentration of zinc (Zn) in the switching layer is higher than an atomic concentration of the third element in the switching layer.

4. The memory device according to claim 1,
wherein the first element is zinc (Zn), and the second element is tellurium (Te).

5. The memory device according to claim 1,
wherein the switching layer further contains a fourth element, the fourth element being at least one element selected from a group consisting of carbon (C), boron (B), nitrogen (N), germanium (Ge), silicon (Si), and aluminum (Al).

6. The memory device according to claim 1,
wherein a sum of atomic concentrations of zinc (Zn), the first element, the second element, and oxygen (O) in the switching layer is equal to or more than 80%.

7. The memory device according to claim 1,
wherein a ratio of a sum of atomic concentrations of zinc (Zn) and oxygen (O) to a sum of atomic concentrations of zinc (Zn), the first element, the second element, and oxygen (O) in the switching layer is equal to or more than 20% and equal to or less than 90%.

8. The memory device according to claim 1,
wherein a ratio of a sum of atomic concentrations of the first element and the second element to a sum of atomic concentrations of zinc (Zn), the first element, the second element, and oxygen (O) in the switching layer is equal to or more than 5% and equal to or less than 65%.

9. The memory device according to claim 2,
wherein the first element is zinc (Zn), and
a ratio of a sum of atomic concentrations of zinc (Zn) and oxygen (O) to a sum of atomic concentrations of zinc (Zn), the first element, the second element, the third element, and oxygen (O) in the switching layer is equal to or more than 40% and equal to or less than 85%.

10. The memory device according to claim 2,
wherein the first element is zinc (Zn), and
a ratio of an atomic concentration of zinc (Zn) to a sum of atomic concentrations of zinc (Zn), the first element, the second element, the third element, and oxygen (O) in the switching layer is equal to or more than 10% and equal to or less than 55%.

11. The memory device according to claim 2,
wherein the first element is zinc (Zn), and
a ratio of a sum of atomic concentrations of zinc (Zn) and the second element to a sum of atomic concentrations of zinc (Zn), the first element, the second element, the third element, and oxygen (O) in the switching layer is equal to or more than 30% and equal to or less than 65%.

12. The memory device according to claim 2,
wherein the first element is zinc (Zn),
an atomic concentration of zinc (Zn) in the switching layer is higher than an atomic concentration of the second element in the switching layer, and
a ratio of a difference between an atomic concentration of zinc (Zn) and an atomic concentration of the second element to a sum of atomic concentrations of zinc (Zn), the first element, the second element, the third element, and oxygen (O) is greater than 20%.

13. The memory device according to claim 1,
wherein at least a part of the switching layer is crystalline.

14. The memory device according to claim 1,
wherein the switching layer contains a mixture of the oxide and the compound.

15. The memory device according to claim 1,
wherein the first conductive layer, the second conductive layer, or the third conductive layer contains at least one material selected from a group consisting of titanium, titanium nitride, carbon, carbon nitride, tungsten, tungsten carbide, and tungsten nitride.

16. The memory device according to claim 1,
wherein the first conductive layer, the second conductive layer, or the third conductive layer contains at least one material selected from a group consisting of hafnium, hafnium boride, magnesium aluminum boride, zirconium, zirconium boride, and titanium boride.

17. The memory device according to claim 1,
wherein the variable resistance layer includes a magnetic tunnel junction.

18. The memory device according to claim 1,
wherein the variable resistance layer has an electrical resistance changing with application of a predetermined voltage, and
the switching layer has a nonlinear current-voltage characteristic that a current increases at a specific threshold voltage.

19. The memory device according to claim 1, further comprising:
a plurality of first wirings; and
a plurality of second wirings crossing the plurality of first wirings,
wherein the memory cell is provided in a region where one of the plurality of first wirings and one of the plurality of second wirings cross each other.

20. A memory device, comprising:
a memory cell including a first conductive layer, a second conductive layer, and a memory layer provided between the first conductive layer and the second conductive layer,
wherein the memory layer contains an oxide of zinc (Zn) and a compound of a first element and a second element, the first element being at least one element selected from a group consisting of zinc (Zn), tin (Sn), gallium (Ga), indium (In), and bismuth (Bi) and the second element being at least one element selected from a group consisting of tellurium (Te), sulfur(S), selenium (Se), and antimony (Sb).

21. The memory device according to claim 20,
wherein the memory layer further contains an oxide of a third element, the third element being at least one element selected from a group consisting of zirconium (Zr), silicon (Si), hafnium (Hf), and aluminum (Al).

22. The memory device according to claim 21,
wherein an atomic concentration of zinc (Zn) in the memory layer is higher than an atomic concentration of the third element in the memory layer.

23. The memory device according to claim 20,
wherein the first element is zinc (Zn), and the second element is tellurium (Te).

24. The memory device according to claim 20,
wherein the memory layer further contains a fourth element, the fourth element being at least one element selected from a group consisting of carbon (C), boron (B), nitrogen (N), germanium (Ge), silicon (Si), and aluminum (Al).

25. The memory device according to claim 20,
wherein the memory layer has a nonlinear current-voltage characteristic that a current increases at a specific threshold voltage, and the threshold voltage changes with application of a predetermined voltage.

26. The memory device according to claim 20, further comprising:
a plurality of first wirings; and
a plurality of second wirings crossing the plurality of first wirings,
wherein the memory cell is provided in a region where one of the plurality of first wirings and one of the plurality of second wirings cross each other.
